(19) United States
(12) Patent Application Publication
(10) Pub. No.: US 2024/0224556 A1
(43) Pub. Date: Jul. 4, 2024

(54) ELECTROLUMINESCENT DEVICE, PRODUCTION METHOD THEREOF, AND DISPLAY DEVICE INCLUDING THE SAME

(71) Applicant: SAMSUNG ELECTRONICS CO., LTD, Suwon-si (KR)

(72) Inventors: You Jung CHUNG, Suwon-si (KR); Sung Woo KIM, Suwon-si (KR); Dongchan KIM, Suwon-si (KR); Ilyoung LEE, Suwon-si (KR); Tae Ho KIM, Suwon-si (KR); Hong Kyu SEO, Suwon-si (KR)

(21) Appl. No.: 18/399,957

(22) Filed: Dec. 29, 2023

(30) Foreign Application Priority Data
Dec. 30, 2022 (KR) 10-2022-0191239

(51) Int. Cl. H10K 50/11; C09K 11/08; H10K 50/16; H10K 71/12

(52) U.S. Cl. CPC H10K 50/11; C09K 11/0811; H10K 50/16; H10K 71/12

(57) ABSTRACT

A method of producing an electroluminescent device, the method including: disposing a light emitting layer including a semiconductor nanoparticle on a first electrode; applying a composition including a zinc oxide nanoparticle onto the light emitting layer to form an electron transport layer, the zinc oxide nanoparticle including a first metal and an alkali metal; and disposing the second electrode on the electron transport layer to produce the electroluminescent device, wherein a preparation of the zinc oxide nanoparticle includes admixing a first solution including a zinc precursor and a first metal precursor in a solvent with a second base and optionally a first base to prepare the zinc oxide nanoparticle, wherein the first base includes an organic base containing a C1 to C50 organic group, and the second base includes an inorganic base including the alkali metal.

### CROSS-REFERENCE TO RELATED APPLICATION

This application claims priority to Korean Patent Application No. 10-2022-0191239 filed in the Korean Intellectual Property Office on Dec. 30, 2022, and all the benefits accruing therefrom under 35 U.S.C. § 119, the content of which in its entirety is herein incorporated by reference.

### BACKGROUND

### 1. Field

The present disclosure relates to a light emitting (e.g., electroluminescent) device, a production method thereof, and a display device including the electroluminescent device.

### 2. Description of the Related Art

A semiconductor nanoparticle (e.g., a semiconductor nanocrystal particle) having a nanometer size may exhibit luminescence properties. For example, a quantum dot including a semiconductor nanocrystal may exhibit a quantum confinement effect. The light emission from the semiconductor nanoparticle may occur when an electron in an excited state resulting from light excitation or an applied voltage moves from a conduction band to a valence band. The semiconductor nanoparticle may be configured to emit light of a desired wavelength region by adjusting a size of the semiconductor nanoparticle, a composition of the semiconductor nanoparticle, or a combination thereof.

The semiconductor nanoparticle may be used, for example, in a light emitting device (e.g., an electroluminescent device) or a display device including the electroluminescent device. There remains a need for an improved light emitting device.

### SUMMARY

An embodiment provides a method of producing a light emitting device that emits light, for example, by applying a voltage to a nanostructure (e.g., a semiconductor nanoparticle such as a quantum dot), for example with or without a separate irradiation light source.

An embodiment provides a light emitting device prepared by the method of an embodiment.

An embodiment provides a display device (e.g., a quantum dot-light emitting diode (QD-LED) display device) that includes a semiconductor nanoparticle such as a quantum dot as a component of a light emitting layer in a pixel configuration (e.g., in a configuration of a blue pixel, a red pixel, a green pixel, or a combination thereof). The display device includes a handheld terminal device, a monitor, a notebook computer, a television, an electronic display board, a camera, or an electronic component for an automatic vehicle.

An embodiment relates to a method for producing an electroluminescent device, the method including:
disposing a light emitting layer including a semiconductor nanoparticle (for example, a plurality of semiconductor nanoparticles) on a first electrode;
applying a composition (e.g., a coating liquid) including a zinc oxide nanoparticle (for example, a plurality of zinc oxide nanoparticles) onto the light emitting layer to form an electron transport layer, the zinc oxide nanoparticle including a first metal different from zinc and an alkali metal; and
disposing a second electrode on the electron transport layer to produce the electroluminescent device,
wherein a preparation of the zinc oxide nanoparticle includes
   admixing a first solution including a zinc precursor and a first metal precursor in a solvent with a second base and optionally a first base to prepare the zinc oxide nanoparticle,
   wherein the first base includes an organic base containing a C1 to C50 organic group (e.g., an aliphatic hydrocarbon group such as an alkyl group), and the second base includes an inorganic base including the alkali metal.

The preparation of the first solution may include dissolving the zinc precursor and the first metal precursor in the solvent (e.g., an organic solvent).

The semiconductor nanoparticle or the light emitting layer may not include cadmium.

The first solution may include or may not include butylamine, ethylamine, ethanolamine, hexamethylenediamine, aniline, hexylamine, or a combination thereof. The first solution may include or may not include a C1 to C12 organic amine, an aromatic amine having a benzene group, or a combination thereof.

The first metal may include an alkaline earth metal, zirconium (Zr), tungsten (W), titanium (Ti), yttrium (Y), aluminum (Al), gallium (Ga), indium (In), tin (Sn), cobalt (Co), vanadium (V), or a combination thereof. The first metal may include an alkali earth metal; and optionally Zr, W, Ti, Y, Al, Ga, In, Sn, Co, V, or a combination thereof.

The alkali metal may include lithium, sodium, potassium, rubidium, cesium, francium, or a combination thereof. The alkali metal may include or may not include lithium.

The first base or the organic base may include a quaternary ammonium salt. The second base or the inorganic base may include a hydroxide of the alkali metal.

A mole ratio (a second base: a first base) between the second base and the first base may be from about 1:0 to about 1:10, from about 1:0.05 to about 1:6, from about 1:0.1 to about 1:4.5, from about 1:0.3 to about 1:3, from about 1:0.8 to about 1:1.5, from about 1:0.9 to about 1:1.3, from about 1:1 to about 1:1.25, or a combination thereof.

A mole ratio of a total sum of the first base and the second base to a total sum of the zinc precursor and the first metal precursor may be from about 1:0.5 to about 1:5, from about 1:0.9 to about 1:2, or a combination thereof.

The method may include or may not include adding an organic acid (e.g., acetic acid) to a reaction system after an addition of the first base or the second base to the first solution.

In ultraviolet-visible (UV-Vis) absorption spectroscopy analysis, the zinc oxide nanoparticle may exhibit a first absorption peak in a range of greater than or equal to about 285 nanometers (nm), greater than or equal to about 290 nm, or greater than or equal to about 292 nm and less than or equal to about 330 nm, or less than or equal to about 300 nm.

In a UV-vis absorption spectrum, the zinc oxide nanoparticle may exhibit a valley that is adjacent to the first absorption peak, and a valley depth (VD) of the valley, defined by Equation 1, may be greater than or equal to about 0.03, or greater than or equal to about 0.035 and less than or equal to about 0.15, less than or equal to about 0.1, or less than or equal to about 0.09:

$$1 - ( {Abs}_{valley} / {Abs}_{first} ) = VD \qquad ( 1 )$$

wherein Abs_{first} is an absorbance at a wavelength of the first absorption peak and Abs_{valley} is an absorbance at a lowest point of the valley.

In an embodiment, the zinc oxide nanoparticle may exhibit a bandgap energy of greater than or equal to about 3.6 eV and less than or equal to about 3.95 eV.

In the zinc oxide nanoparticle or the electron transport layer, a mole ratio of the alkali metal to the first metal (for example, magnesium) may be greater than or equal to about 0.05:1, greater than or equal to about 0.1:1, greater than or equal to about 0.3:1, or greater than or equal to about 0.35:1. In the zinc oxide nanoparticle or the electron transport layer, a mole ratio of the alkali metal to the first metal may be less than or equal to about 1.5:1, less than or equal to about 1:1, less than or equal to about 0.9:1, or less than or equal to about 0.77:1.

In the zinc oxide nanoparticle or the electron transport layer, a mole ratio of the alkali metal to zinc may be greater than or equal to about 0.01:1, greater than or equal to about 0.05:1, greater than or equal to about 0.08:1, or greater than or equal to about 0.1:1. In the zinc oxide nanoparticle, or the electron transport layer, a mole ratio of the alkali metal to zinc may be less than or equal to about 0.5:1, or less than or equal to about 0.3:1, less than or equal to about 0.077:1, less than or equal to about 0.075:1, less than or equal to about 0.049:1, or less than or equal to about 0.045:1.

In the zinc oxide nanoparticle or the electron transport layer, a mole ratio of a sum of the first metal and the alkali metal to zinc [(the first metal+the alkali metal):zinc] may be greater than or equal to about 0.1:1, greater than or equal to about 0.115:1, greater than or equal to about 0.15:1, greater than or equal to about 0.2:1, greater than or equal to about 0.21:1, or greater than or equal to about 0.22:1 and less than or equal to about 1:1, less than or equal to about 0.8:1, or less than or equal to about 0.5:1.

A mole ratio of magnesium to zinc in the zinc oxide nanoparticle or the electron transport layer may be less than or equal to about 0.5:1, less than or equal to about 0.3:1, less than or equal to about 0.25:1, or less than or equal to about 0.2:1. A mole ratio of magnesium to zinc in the zinc oxide nanoparticle or the electron transport layer may be greater than or equal to about 0.01:1, greater than or equal to about 0.03:1, greater than or equal to about 0.05:1, greater than or equal to about 0.07:1, greater than or equal to about 0.09:1, greater than or equal to about 0.1:1, greater than or equal to about 0.12:1, greater than or equal to about 0.14:1, or greater than or equal to about 0.16:1.

In an embodiment, the zinc oxide nanoparticle may include rubidium, and in X-ray photoelectron spectroscopy (XPS) analysis, it may exhibit a peak of Rb3p in a range of a binding energy of from about 230 electronvolts (eV) to about 245 eV or from about 235 eV to about 240 eV.

The solvent may include a first organic solvent, and optionally a second organic solvent. The first organic solvent may include an organic sulfur solvent (e.g., a sulfoxide solvent such as dimethyl sulfoxide). The second organic solvent may include C1 to C10 alcohols. The second organic solvent may be miscible with the first organic solvent or water.

In an embodiment, an electroluminescent device includes:
a first electrode and a second electrode spaced apart from each other (e.g., each electrode having a surface opposite the other);
a light emitting layer disposed between the first electrode and the second electrode; and
an electron transport layer disposed between the light emitting layer and the second electrode,
wherein the light emitting layer is configured to emit a first light,
wherein the light emitting layer includes a semiconductor nanoparticle (e.g., a plurality of semiconductor nanoparticles),
wherein the electron transport layer includes a zinc oxide nanoparticle (e.g., a plurality of zinc oxide nanoparticles),
wherein the zinc oxide nanoparticle has a size of greater than or equal to about 1 nanometer and less than or equal to about 50 nanometers, and includes a first metal different from zinc and an alkali metal,
wherein
the first metal includes an alkaline earth metal and
the alkali metal includes sodium, potassium, rubidium, cesium, francium, or a combination thereof.

The first metal may further include or may not include zirconium, tungsten, titanium, yttrium, aluminum, gallium, indium, tin, cobalt, vanadium, or a combination thereof.

The alkali metal may further include lithium. The alkali metal may not include lithium. The first light may be blue light. The first light may have a peak emission wavelength of greater than or equal to about 440 nm and less than or equal to about 480 nm.

The electroluminescent device may further include a hole auxiliary layer between the light emitting layer and the first electrode. The hole auxiliary layer may include a hole transport layer (e.g., including an organic compound), a hole injection layer, or a combination thereof.

The semiconductor nanoparticle or the light emitting layer may not include cadmium, lead, mercury, or a combination thereof.

The semiconductor nanoparticle may include a first semiconductor nanocrystal including zinc, selenium, and tellurium, and a second semiconductor nanocrystal including a zinc chalcogenide, the second semiconductor nanocrystal being different from the first semiconductor nanocrystal.

The semiconductor nanoparticle may include a first semiconductor nanocrystal including (a Group III-V compound or an indium phosphide compound including) indium, phosphorus, and optionally zinc; and a second semiconductor nanocrystal including a zinc chalcogenide and different from the first semiconductor nanocrystal.

The semiconductor nanoparticle may include a zinc chalcogenide, the zinc chalcogenide may include tellurium, and the semiconductor nanoparticle may be configured to emit blue light.

The semiconductor nanoparticle may have a core-shell structure that includes a core including the first semiconductor nanocrystal and a shell disposed on the core and including the second semiconductor nanocrystal.

In UV-Vis absorption spectroscopy analysis, the zinc oxide nanoparticle may have a first absorption peak wavelength in a range of greater than or equal to about 285 nm, greater than or equal to about 290 nm, or greater than or equal to about 292 nm and less than or equal to about 330 nm, or less than or equal to about 300 nm.

In a UV-vis absorption spectrum, the zinc oxide nanoparticle may exhibit a valley that is adjacent to a first absorption peak, and a valley depth (VD) defined by Equation (1) may be greater than or equal to about 0.03, or greater than or equal to about 0.035 and less than or equal to about 0.15, less than or equal to about 0.1, or less than or equal to about 0.09:

$$1 - ( {Abs}_{valley} / {Abs}_{first} ) = VD \qquad ( 1 )$$

wherein Abs_{first} is an absorbance at a wavelength of the first absorption peak and Abs_{valley} is an absorbance at a lowest point of the valley.

The zinc oxide nanoparticle or the electron transport layer may exhibit a bandgap energy of greater than or equal to about 3.6 eV and less than or equal to about 3.95 eV.

In the zinc oxide nanoparticle, or the electron transport layer, a mole ratio of the alkali metal to the first metal (for example, magnesium) may be greater than or equal to about 0.05:1, greater than or equal to about 0.1:1, greater than or equal to about 0.3:1, or greater than or equal to about 0.35:1. In the zinc oxide nanoparticle or the electron transport layer, a mole ratio of the alkali metal to the first metal may be less than or equal to about 1.5:1, less than or equal to about 1:1, less than or equal to about 0.9:1, less than or equal to about 0.77:1, or less than or equal to about 0.65:1.

In the zinc oxide nanoparticle, or the electron transport layer, a mole ratio of the alkali metal to zinc may be greater than or equal to about 0.01:1, greater than or equal to about 0.02:1, greater than or equal to about 0.03:1, greater than or equal to about 0.035:1, greater than or equal to about 0.05:1, greater than or equal to about 0.08:1, or greater than or equal to about 0.1:1. In the zinc oxide nanoparticle or the electron transport layer, a mole ratio of the alkali metal to zinc may be less than or equal to about 0.5:1, less than or equal to about 0.3:1, less than or equal to about 0.1:1, less than or equal to about 0.08:1, less than or equal to about 0.077:1, less than or equal to about 0.075:1, less than or equal to about 0.049:1, or less than or equal to about 0.045:1.

In the zinc oxide nanoparticle or the electron transport layer, a mole ratio of a sum of the first metal and the alkali metal to zinc [(the first metal+the alkali metal):zinc] may be greater than or equal to about 0.1:1, greater than or equal to about 0.115:1, greater than or equal to about 0.15:1, greater than or equal to about 0.2:1, greater than or equal to about 0.21:1, or greater than or equal to about 0.22:1 and less than or equal to about 1:1, less than or equal to about 0.8:1, less than or equal to about 0.5:1, or less than or equal to about 0.3:1.

In the zinc oxide nanoparticle or the electron transport layer, a mole ratio of magnesium to zinc may be less than or equal to about 0.5:1, less than or equal to about 0.3:1, less than or equal to about 0.25:1, or less than or equal to about 0.2:1. In the zinc oxide nanoparticle or the electron transport layer, a mole ratio of magnesium to zinc may be greater than or equal to about 0.01:1, greater than or equal to about 0.03:1, greater than or equal to about 0.05:1, greater than or equal to about 0.07:1, greater than or equal to about 0.09:1, greater than or equal to about 0.1:1, greater than or equal to about 0.12:1, greater than or equal to about 0.14:1, or greater than or equal to about 0.16:1.

The zinc oxide nanoparticle may have a size or an average size (hereinafter, “size”) of greater than or equal to about 1 nm, or greater than or equal to about 3 nm. The zinc oxide nanoparticle may have the size of less than or equal to about 50 nm, less than or equal to about 10 nm, less than or equal to about 8 nm, less than or equal to about 5 nm, or less than or equal to about 4 nm.

A thickness of the electron transport layer may be greater than or equal to about 5 nm. A thickness of the electron transport layer may be less than or equal to about 70 nm.

The electroluminescent device, or the light emitting layer, may be configured to emit green light with application of a voltage. The electroluminescent device or the light emitting layer may be configured to emit blue light with application of a voltage. The electroluminescent device or the light emitting layer may be configured to emit red light with application of a voltage.

The electroluminescent device has a maximum external quantum efficiency of greater than or equal to about 6%, greater than or equal to about 7%, greater than or equal to about 8%, greater than or equal to about 9%, greater than or equal to about 10%, greater than or equal to about 11%, greater than or equal to about 12%, greater than or equal to about 13%, or greater than or equal to about 14%. The maximum external quantum efficiency may be from about 6% to about 50%, or from about 10% to about 40%.

The electroluminescent device may have a maximum luminance of greater than or equal to about 60,000 candela per square meter (cd/m²), greater than or equal to about 70,000 cd/m², greater than or equal to about 80,000 cd/m², greater than or equal to about 90,000 cd/m², greater than or equal to about 100,000 cd/m², or greater than or equal to about 300,000 cd/m². The maximum luminance may be less than or equal to about 5,000,000 cd/m², less than or equal to about 3,000,000 cd/m², less than or equal to about 2,000,000 cd/m², or less than or equal to about 1,000,000 cd/m².

The electroluminescent device may exhibit T50 of greater than or equal to about 90 hours, greater than or equal to about 100 hours, greater than or equal to about 150 hours, greater than or equal to about 250 hours, greater than or equal to about 261 hours, greater than or equal to about 265 hours, greater than or equal to about 270 hours, greater than or equal to about 300 hours, greater than or equal to about 350 hours, greater than or equal to about 400 hours, greater than or equal to about 480 hours, greater than or equal to about 500 hours, or greater than or equal to about 600 hours (e.g., as being measured at an initial luminance of 650 nit). The T50 may be from about 150 hours to about 2000 hours, from about 250 hours to about 1500 hours, from about 300 hours to about 1000 hours, or a combination thereof.

The electroluminescent device may exhibit a T90 of greater than or equal to about 10 hours, greater than or equal to about 20 hours, greater than or equal to about 30 hours, greater than or equal to about 40 hours, greater than or equal to about 50 hours, greater than or equal to about 60 hours, greater than or equal to about 70 hours, greater than or equal to about 80 hours, greater than or equal to about 90 hours, or greater than or equal to about 100 hours (e.g., as being driven at an initial luminance of 650 nit). The T90 may be from about 55 hours to about 1000 hours, from about 62 hours to about 1000 hours, from about 75 hours to about 800 hours, from about 82 hours to about 700 hours, or a combination thereof.

In an embodiment, a display device or an electronic apparatus may include the electroluminescent device.

The display device may include a first pixel and a second pixel configured to emit light of a color differing from that of the first pixel. In the first pixel, the second pixel, or both, the electroluminescent device according to an embodiment may be disposed. In an embodiment, the display device may further include a blue pixel, a red pixel, a green pixel, or a combination thereof. In the display device, the red pixel may include a red light emitting layer including a plurality of red light emitting semiconductor nanoparticles, the green pixel may include a green light emitting layer including a plurality of green light emitting semiconductor nanoparticles, and the blue pixel may include a blue light emitting layer including a plurality of blue light emitting semiconductor nanoparticles. The electroluminescent device according to an embodiment may be disposed in the blue pixel, the red pixel, or the green pixel, for example, in the blue pixel.

The display device or an electronic apparatus may include (or may be) an augmented reality (AR) device, a (virtual reality) VR device, a handheld terminal (e.g., device), a monitor, a notebook computer, a television, an electronic display board, a camera, an electronic display component for an automatic vehicle, or an electric car.

According to embodiments, an electroluminescent device capable of exhibiting improved life-span and electroluminescent characteristics at the same time is provided.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1 is a schematic cross-sectional view of an embodiment of an electroluminescent device.

FIG. 2 is a schematic cross-sectional view of an embodiment of an electroluminescent device.

FIG. 3 is a schematic cross-sectional view of an embodiment of an electroluminescent device.

FIG. 4A, FIG. 4B, and FIG. 4C are each a graph of intensity (arbitrary units, a.u.) vs. binding energy (electronvolts, eV) for Zn2p, O1s, and Rb3p, respectively, and shows the results of X-ray photoelectron spectroscopy (XPS) analysis for the zinc oxide nanoparticle prepared in Preparation Example 1 and Comparative Preparation Example 1.

FIG. 5 is a graph of intensity (arbitrary units, a.u.) vs. wavelength (nanometers, nm), and shows the results of UV-Vis absorption spectroscopy analysis for the zinc oxide nanoparticles prepared in Preparation Examples 1 to 5 and Comparative Preparation Example 1.

FIG. 6 is a graph of weight (percent, %) vs. temperature (° C.) and Derivative weight (Deriv. weight) vs. temperature (° C.), and shows the results (TGA and DTG graphs) of a thermogravimetric analysis for the zinc oxide nanoparticles prepared in Preparation Examples 1 and 2 and Comparative Preparation Example 1.

FIG. 7 is graph of intensity (arbitrary units, a.u.) vs. wavenumber (inverse centimeter, cm⁻¹), and shows the results of a Fourier-transform infrared (FT-IR) spectroscopy analysis for the zinc oxide nanoparticle prepared in Preparation Example 1 and Comparative Preparation Example 1.

### DETAILED DESCRIPTION

Advantages and characteristics of this disclosure, and a method for achieving the same, will become evident referring to the following example embodiments together with the drawings attached hereto. However, this invention may, be embodied in many different forms, the embodiments should not be construed as being limited to the embodiments set forth herein. Rather, these embodiments are provided so that this disclosure will be thorough and complete, and will fully convey the scope of the invention to those skilled in the art. Like reference numerals refer to like elements throughout.

In order to clearly explain the present disclosure, parts irrelevant to the description are omitted, and the same reference numerals are assigned to the same or similar elements throughout the specification. In the drawings, the thickness of layers, films, panels, regions, etc., are exaggerated for clarity. And in the drawings, for convenience of description, the thickness of some layers and regions are exaggerated. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Also, to be disposed “on” the reference portion means to be disposed above or below the reference portion and does not necessarily mean “above”.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

It will be understood that, although the terms “first,” “second,” “third,” etc., may be used herein to describe various elements, components, regions, layers and/or sections, these elements, components, regions, layers and/or sections should not be limited by these terms. These terms are only used to distinguish one element, component, region, layer or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as being limited to “a” or “an.” “Or” means “and/or.”

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

As used herein, the term “cross-sectional phase” means a case in which a cross-section of a given object is cut, for example, in a substantially vertical direction and is viewed laterally.

Unless otherwise defined, all terms (including technical and scientific terms) used herein have the same meaning as commonly understood by one of ordinary skill in the art to which this disclosure belongs. It will be further understood that terms, such as those defined in commonly used, e.g., non-technical, dictionaries, should be interpreted as having a meaning that is consistent with their meaning in the context of the relevant art and the present disclosure, and will not be interpreted in an idealized or overly formal sense unless expressly so defined herein.

As used herein, values of a work function, a conduction band, a valence band, a lowest unoccupied molecular orbital (LUMO), or highest occupied molecular orbital (HOMO) energy level is expressed as an absolute value from a vacuum level. In addition, when the work function or the energy level is referred to be “deep,” “high” or “large,” the work function or the energy level has a large absolute value based on “0 electron volts (eV)” of the vacuum level, while when the work function or the energy level is referred to be “shallow,” “low,” or “small,” the work function or energy level has a small absolute value based on “0 eV” of the vacuum level. In an aspect, work function herein refers to a minimum energy required to remove an electron from e.g., a metal surface to vacuum.

As used herein, the average (value) may be mean or median. In an embodiment, the average (value) may be a mean value.

As used herein, the term “peak emission wavelength” is the wavelength at which a given emission spectrum of the light reaches its maximum.

As used herein, the term “first absorption peak” refers to a main excitonic peak appearing first from the longest wavelength region of a UV-vis absorption spectrum (i.e., appearing in the lowest energy region in the UV-Vis absorption spectrum), and the term “first absorption peak wavelength” or “wavelength of the first absorption peak” refers to the wavelength at which the first absorption peak reaches a maximum intensity.

As used herein, the term “Group” may refer to a group of Periodic Table.

As used herein, “Group I” refers to Group IA and Group IB, and examples may include Li, Na, K, Rb, and Cs, but are not limited thereto.

As used herein, “Group II” refers to Group IIA and Group IIB, and examples of Group II metal may be Cd, Zn, Hg, and Mg, but are not limited thereto.

As used herein, “Group III” refers to Group IIIA and Group IIIB, and examples of Group IIIA metal may be Al, In, Ga, and Tl, and examples of Group IIIB may be scandium, yttrium, or the like, but are not limited thereto.

As used herein, “Group IV” refers to Group IVA and Group IVB, and examples of a Group IVA metal may be Si, Ge, and Sn, and examples of Group IVB metal may be titanium, zirconium, hafnium, or the like, but are not limited thereto.

As used herein, “Group V” includes Group VA and includes nitrogen, phosphorus, arsenic, antimony, and bismuth, but is not limited thereto.

As used herein, “Group VI” includes Group VIA and includes sulfur, selenium, and tellurium, but is not limited thereto.

As used herein, “metal” includes a semi-metal such as Si.

As used herein, a number of carbon atoms in a group or a molecule may be referred to as a subscript (e.g., C₆₋₅₀) or as a non-subscript (e.g., C6 to C50).

As used herein, when a definition is not otherwise provided, “substituted” refers to replacement of at least one hydrogen of a compound or a group with a C1 to C30 alkyl group, a C2 to C30 alkenyl group, a C2 to C30 alkynyl group, a C6 to C30 aryl group, a C7 to C30 alkylaryl group, a C1 to C30 alkoxy group, a C1 to C30 heteroalkyl group, a C3 to C30 heteroaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

As used herein, when a definition is not otherwise provided, “hydrocarbon” or “hydrocarbon group” refers to a compound or a group including carbon and hydrogen (e.g., alkyl, alkenyl, alkynyl, or aryl group). The hydrocarbon group may be a monovalent group or a group having a valence of greater than one formed by removal of a, e.g., one or more, hydrogen atoms from alkane, alkene, alkyne, or arene. In the hydrocarbon or hydrocarbon group, a, e.g., at least one, methylene may be replaced by an oxide moiety, a carbonyl moiety, an ester moiety, —NH—, or a combination thereof. Unless otherwise stated to the contrary, the hydrocarbon or the hydrocarbon group (alkyl, alkenyl, alkynyl, or aryl) may have 1 to 60, 2 to 32, 3 to 24, or 4 to 12 carbon atoms.

As used herein, when a definition is not otherwise provided, “alkyl” refers to a linear or branched saturated monovalent hydrocarbon group (methyl, ethyl, hexyl, etc.). In an embodiment, an alkyl group may have from 1 to 50 carbon atoms, or 1 to 18 carbon atoms, or 1 to 12 carbon atoms.

As used herein, when a definition is not otherwise provided, “alkenyl” refers to a linear or branched monovalent hydrocarbon group having a carbon-carbon double bond. In an embodiment, an alkenyl group may have from 2 to 50 carbon atoms, or 2 to 18 carbon atoms, or 2 to 12 carbon atoms.

As used herein, when a definition is not otherwise provided, “alkynyl” refers to a linear or branched monovalent hydrocarbon group having a carbon-carbon triple bond. In an embodiment, an alkynyl group may have from 2 to 50 carbon atoms, or 2 to 18 carbon atoms, or 2 to 12 carbon atoms.

As used herein, when a definition is not otherwise provided, “aryl” refers to a group formed by removal of a, e.g., at least one, hydrogen from an arene (e.g., a phenyl or naphthyl group). In an embodiment, an aryl group may have 6 to 50 carbon atoms, or 6 to 18 carbon atoms, or 6 to 12 carbon atoms.

As used herein, when a definition is not otherwise provided, “hetero” refers to inclusion of 1 to 3 heteroatoms, e.g., N, O, S, Si, P, or a combination thereof.

As used herein, when a definition is not otherwise provided, “alkoxy” refers to an alkyl group linked to oxygen (e.g., alkyl-O—) for example, a methoxy group, an ethoxy group, or a sec-butyloxy group.

As used herein, when a definition is not otherwise provided, “amine” is a compound represented by NR₃, wherein each R is independently hydrogen, a C1-C12 alkyl group, a C7-C20 alkylarylene group, a C7-C20 arylalkylene group, or a C6-C18 aryl group.

As used herein, the expression “not including cadmium (or other harmful heavy metal)” may refer to the case in which a concentration of cadmium (or another heavy metal deemed harmful) may be less than or equal to about 100 parts per million by weight (ppmw), less than or equal to about 50 ppmw, less than or equal to about 10 ppmw, less than or equal to about 1 ppmw, less than or equal to about 0.1 ppmw, less than or equal to about 0.01 ppmw, or zero. In an embodiment, substantially no amount of cadmium (or other toxic heavy toxic metal) may be present or, if present, an amount of cadmium (or other toxic heavy metal) may be less than or equal to a detection limit of a given analysis tool (e.g., an inductively coupled plasma atomic emission spectroscopy instrument) or as an impurity level.

Unless mentioned to the contrary, a numerical range recited herein is inclusive. Unless mentioned to the contrary, a numerical range recited herein includes any real number within the endpoints of the stated range and includes the endpoints thereof. In this specification, a numerical endpoint or an upper or lower limit value (e.g., recited either as a “greater than or equal to value” “at least value” or a “less than or equal to value” or recited with “from” or “to”) may be used to form a numerical range of a given feature. In other words, the upper and lower endpoints set forth for various numerical values may be independently combined to provide a range.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±5% of the stated value.

As used herein, a nanoparticle is a structure having a, e.g., at least one, region or characteristic dimension with a nanoscale dimension. In an embodiment, a dimension (or an average dimension) of the nanostructure is less than or equal to about 500 nanometers (nm), less than or equal to about 300 nm, less than or equal to about 250 nm, less than or equal to about 150 nm, less than or equal to about 100 nm, less than or equal to about 50 nm, or less than or equal to about 30 nm, and may be greater than about 0.1 nm or about 1 nm. In an embodiment, the nanoparticle may have any suitable shape. The nanoparticle (e.g., a semiconductor nanoparticle or a metal oxide nanoparticle) may include a nanowire, a nanorod, a nanotube, a branched nanostructure, a nanotetrapod, a nanotripod, a nanobipod, a nanocrystal, a nanodot, a multi-pod type shape such as at least two pods, or the like and is not limited thereto. The nanoparticle can be, e.g., substantially crystalline, substantially monocrystalline, polycrystalline, (for example, at least partially) amorphous, or a combination thereof.

In an embodiment, a semiconductor nanoparticle such as a quantum dot may exhibit quantum confinement or exciton confinement. As used herein, the term “quantum dot” or “semiconductor nanostructure” is not limited in a shape thereof unless otherwise defined. A semiconductor nanoparticle or a quantum dot may have a size smaller than a Bohr excitation diameter for a bulk crystal material having an identical composition and may exhibit a quantum confinement effect. The semiconductor nanoparticle or the quantum dot may emit light corresponding to a bandgap energy thereof by controlling a size of a nanocrystal acting as an emission center.

As used herein, the term “T50” is a time (hours, hr) taken for the brightness (e.g., luminance) of a given device decreases to 50% of the initial brightness (100%) when the given device is started to be driven, e.g., operated, at a predetermined initial brightness (e.g., 650 nit).

As used herein, the term “T90” is a time (hr) taken for the brightness (e.g., luminance) of a given device decreases to 90% of the initial brightness (100%) as the given device is started to be driven at a predetermined initial brightness (e.g., 650 nit).

As used herein, the phrase “external quantum efficiency (EQE)” is a ratio of the number of photons emitted from a light emitting device (LED) such as electroluminescence device to the number of electrons passing through the device and can be a measurement as to how efficiently a given device converts electrons to photons and allows the photons to escape. The EQE may be determined by the following equation:

EQE=(efficiency of injection)×((solid-state)quantum yield)×(efficiency of extraction)

wherein the efficiency of injection is a proportion of electrons passing through the device that are injected into the active region, the quantum yield is a proportion of all electron-hole recombination in the active region that are radiative and produce photons, and the efficiency of extraction is a proportion of photons generated in the active region that escape from the given device.

As used herein, a maximum EQE is a greatest value of the EQE.

As used herein, a maximum luminance is the highest value of luminance for a given device.

As used herein, the phrase, quantum efficiency, may be used interchangeably with the phrase, quantum yield. In an embodiment, the quantum efficiency may be a relative quantum yield or an absolute quantum yield, for example, which can be readily measured by any suitable, e.g., commercially available, equipment. The quantum efficiency (or quantum yield) may be measured in a solution state or a solid state (in a composite). In an embodiment, “quantum yield (or quantum efficiency)” may be a ratio of photons emitted to photons absorbed, e.g., by a nanostructure or population of nanostructures. In an embodiment, the quantum efficiency may be determined by any suitable method. For example, there may be two methods for measuring the fluorescence quantum yield or efficiency: the absolute method and the relative method.

The absolute method directly obtains the quantum yield by detecting all sample fluorescence through the use of an integrating sphere. In the relative method, the fluorescence intensity of a standard sample (e.g., a standard dye) may be compared with the fluorescence intensity of an unknown sample to calculate the quantum yield of the unknown sample. Coumarin 153, Coumarin 545, Rhodamine 101 inner salt, Anthracene, and Rhodamine 6G may be used as standard dye, depending on the photoluminescence (PL) wavelengths thereof, but are not limited thereto.

A bandgap energy of a semiconductor nanoparticle may vary with a size and a composition of a nanocrystal. For example, as a size of the semiconductor nanoparticle increases, the bandgap energy of the semiconductor nanoparticle may become smaller, e.g., narrower, and the semiconductor nanoparticle may emit light having an increased wavelength. A semiconductor nanocrystal may be used as a light emitting material in various fields of, e.g., such as in, a display device, an energy device, or a bio light emitting device.

A semiconductor nanoparticle based electroluminescent device (hereinafter, also referred to as a QD-LED) may emit light by applying a voltage and includes a semiconductor nanoparticle or a quantum dot as a light emitting material. The QD-LED is different from an organic light emitting diode (OLED) in light of a specific emission principle and may exhibit light emission with more desirable optical properties, e.g., higher color (e.g., red, green, and blue) purity, and improved color reproducibility and is drawing attention as a material for a next generation display device. A method of producing the QD-LED may include a solution process, which may lower, e.g., reduce, a manufacturing cost. In addition, a semiconductor nanoparticle in the QD-LED may be based on an inorganic material, contributing to realization of increased display (light emission) stability over time. However, it is still desirable to develop a technology that can further improve device properties and life characteristics for the QD-LED.

In an embodiment, a structure of the QD-LED includes a light emitting layer (EML) disposed between two electrodes (e.g., an anode and a cathode), and one or more auxiliary layers (including electron transport layer (ETL) and optionally a hole transport layer (HTL)) provided on opposite surfaces of the light emitting layer, providing a charge balance and assisting an operation of a device. In an embodiment, the QD-LED may include an organic or inorganic charge auxiliary layer (e.g., an organic or inorganic hole transport layer). A QD-LED according to an embodiment may include an inorganic material (e.g., a zinc oxide nanoparticle) in an electron auxiliary layer such as an electron transport layer (ETL). In the QD-LED of an embodiment, the electron auxiliary layer containing the inorganic material on the light emitting layer may be readily formed through a solution process, for example, a relatively low-temperature (e.g., room temperature) process, and the electron auxiliary layer may provide improved mobility of electrons. A hole injected from the anode and an electron injected from the cathode may be supplied to the light emitting layer through the auxiliary layers and an exciton may be formed and light may be emitted therefrom.

In the light emitting layer, a quantum dot capable of exhibiting a practically applicable level of an electroluminescent property may include a harmful heavy metal such as cadmium (Cd), lead, mercury, or a combination thereof. Accordingly, it is desirable to provide a light emitting device or a display device having a light emitting layer substantially free of the harmful heavy metal. In a QD-LED, currently reported and satisfactory electroluminescent properties are mostly based on a cadmium-based (i.e., cadmium-containing) LED, and there is room for improvement in a QD-LED device using an environmentally-friendly quantum dot and for example emitting blue light that does not include cadmium or other harmful heavy metals.

In an embodiment of a QD-LED device, a zinc oxide nanoparticle prepared in the method of an embodiment and having the features described herein may be included in the electronic auxiliary layer, and accordingly, the QD-LED including a cadmium free semiconductor nanoparticle in a light-emitting layer may exhibit a desired level of an electroluminescent property and an increased lifespan.

In an embodiment, an electroluminescent device may be a device configured to emit a desired light by applying a voltage, for example, with or without a separate light source.

In an embodiment, an electroluminescent device includes a first electrode 1 and a second electrode 5 spaced apart from each other (e.g., each having a surface opposite the other, i.e., each with a surface facing the other); a light emitting layer 3 disposed between the first electrode 1 and the second electrode 5; and an electron transport layer 4 disposed between the light emitting layer 3 and the second electrode 5.

In an embodiment, a method for producing the electroluminescent device includes:
disposing (e.g., forming) a light emitting layer including a semiconductor nanoparticle (for example, a plurality of semiconductor nanoparticles) on a first electrode;
applying a composition (e.g., a coating liquid) including a zinc oxide nanoparticle (for example, a plurality of zinc oxide nanoparticles) onto the light emitting layer to form an electron transport layer, the zinc oxide nanoparticle including a first metal different from zinc and an alkali metal; and
disposing a second electrode on the electron transport layer to produce the electroluminescent device,
wherein a preparation of the zinc oxide nanoparticle comprises
   admixing a first solution including a zinc precursor and a first metal precursor in a solvent with a second base and optionally a first base to form the zinc oxide nanoparticle,
   wherein the first base includes an organic base containing a C1 to C50 organic group (e.g., an aliphatic hydrocarbon group such as an alkyl group), and the second base includes an inorganic base including the alkali metal.

The method may further include preparing the composition. In the method of an embodiment, the formed electron transport layer may be subject to a heat-treating. The method may further include dissolving the zinc precursor and the first metal precursor in the solvent to prepare the first solution. The admixing may involve conducting a reaction for the precursors to form the zinc oxide nanoparticle.

In the method of an embodiment, the composition (e.g., the coating liquid) may be a dispersion. In an embodiment, the dispersion may have a dispersed phase of a solid, and a continuous medium including a liquid. In an embodiment, the dispersion may be a colloidal dispersion in which the dispersed phase has a dimension of greater than or equal to about 1 nm, for example, greater than or equal to about 2 nm, greater than or equal to about 3 nm, greater than or equal to about 4 nm, greater than or equal to about 5 nm, or greater than or equal to about 10 nm and several micrometers (um) or less, e.g., less than or equal to about 2 um, less than or equal to about 1 um, less than or equal to about 900 nm, less than or equal to about 800 nm, less than or equal to about 700 nm, less than or equal to about 600 nm, or less than or equal to about 500 nm.

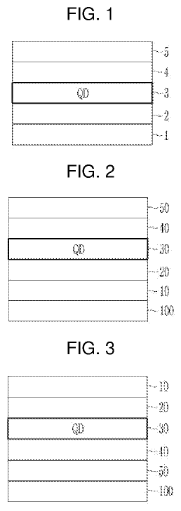

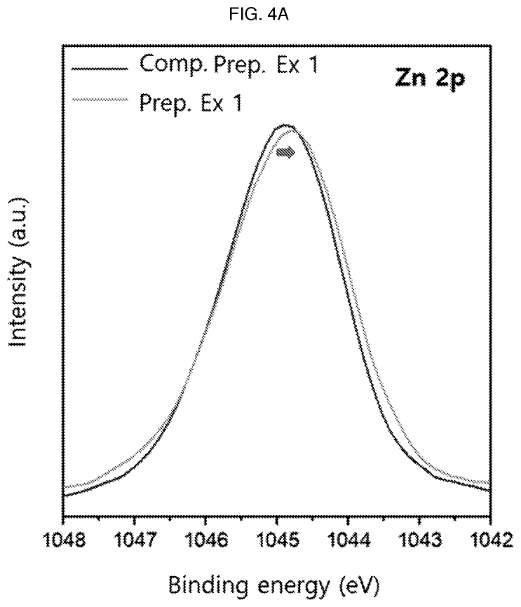

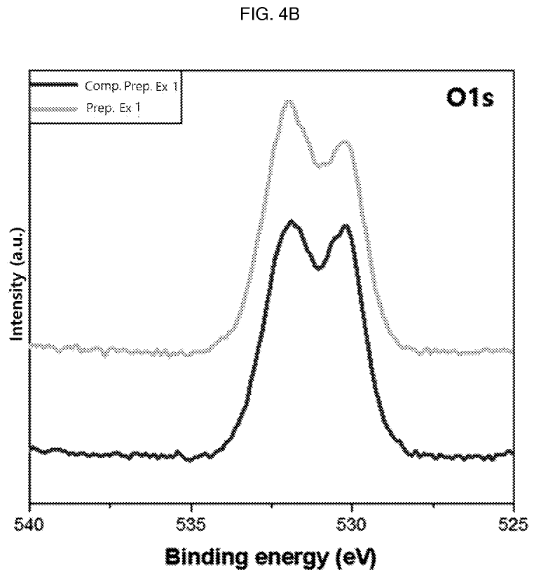

In an embodiment, the electroluminescent device may further include a hole auxiliary layer 2 between the light emitting layer and the first electrode. The hole auxiliary layer may include a hole transport layer, a hole injection layer, or a combination thereof. The hole auxiliary layer may include an organic compound. See FIG. 1, FIG. 2, and FIG. 3.

In an embodiment, the first electrode or the second electrode includes an anode or a cathode. The first electrode may include an anode, and the second electrode may include a cathode. The first electrode may include a cathode and the second electrode may include an anode. In an embodiment, the second electrode includes a cathode. In the electroluminescent device of an embodiment, the first electrode 10 or the second electrode 50 may be disposed on a (transparent) substrate 100. The transparent substrate may be a light extraction surface. (see FIG. 2 and FIG. 3). The light emitting layer may be disposed in a pixel (or a subpixel) of a display device described herein.

Referring to FIGS. 2 and 3, in an electroluminescent device of an embodiment, a light emitting layer 30 may be disposed between a first electrode (e.g., anode) 10 and a second electrode (e.g., cathode) 50. The cathode 50 may include an electron injection conductor. The anode 10 may include a hole injection conductor. The work functions of the electron or hole injection conductors included in the cathode and the anode may be appropriately adjusted and are not particularly limited. For example, the cathode may have a relatively small work function and the anode may have a relatively large work function, or vice versa.

The electron or hole injection conductors may include a metal-based (i.e., metal-containing) material (e.g., a metal, a metal compound, an alloy, or a combination thereof) such as aluminum, magnesium, tungsten, nickel, cobalt, platinum, palladium, calcium, LiF, etc.; a metal oxide such as gallium indium oxide or indium tin oxide (ITO); or a conductive polymer (e.g., having a relatively high work function) such as polyethylene dioxythiophene, but are not limited thereto.

The first electrode, the second electrode, or a combination thereof may be a light-transmitting electrode or a transparent electrode. In an embodiment, both the first electrode and the second electrode may be a light-transmitting electrode. The first electrode, the second electrode, or a combination thereof may be patterned electrodes.

The first electrode, the second electrode, or a combination thereof may be disposed on a (e.g., insulating) substrate 100. The substrate 100 may be optically transparent (e.g., may have a light transmittance of greater than or equal to about 50%, greater than or equal to about 60%, greater than or equal to about 70%, greater than or equal to about 80%, greater than or equal to about 85%, or greater than or equal to about 90% and, for example, less than or equal to about 99%, or less than or equal to about 95%). The substrate may have a transmittance of greater than or equal to about 50%, greater than or equal to about 60%, greater than or equal to about 70%, greater than or equal to about 80%, or greater than or equal to about 90% for light emitted from semiconductor nanoparticles that are described herein. The substrate 100 may include a region for a blue pixel, a region for a red pixel, a region for a green pixel, or a combination thereof. In an embodiment, a thin film (e.g., film) transistor may be disposed in each region of the substrate, but it is not limited thereto. In an embodiment, a source electrode or a drain electrode of the thin film transistor may be electrically connected to the first electrode or the second electrode.

The substrate 100 may be a rigid or a flexible substrate. The substrate 100 may be a substrate including an insulating material. The substrate may include glass; various polymers such as a polyester of polyethylene terephthalate (PET), polyethylene naphthalate (PEN), and the like, polycarbonate, and polyacrylate; a polysiloxane (e.g., polydimethylsiloxane (PDMS)); an inorganic material such as Al₂O₃ or ZnO; or a combination thereof but is not limited thereto. A thickness of the substrate may be appropriately selected taking into consideration a substrate material but is not particularly limited. In an embodiment, the light-transmitting electrode may be disposed on a (e.g., insulating) transparent substrate.

The light-transmitting electrode may include, for example, a transparent conductor such as indium tin oxide (ITO) or indium zinc oxide (IZO), gallium indium tin oxide, zinc indium tin oxide, titanium nitride, polyaniline, LiF/Mg:Ag, or the like, or a metal thin film of a single layer or a plurality of layers, but is not limited thereto. In an embodiment, one of the first electrode or the second electrode may be an opaque electrode, the opaque electrode may include an opaque conductor such as aluminum (Al), a lithium-aluminum (Li:Al) alloy, a magnesium-silver (Mg:Ag) alloy, or lithium fluoride-aluminum (LiF:Al).

The thickness of each electrode (the first electrode, the second electrode, or both) is not particularly limited and may be appropriately selected taking into consideration device efficiency. For example, the thickness of the electrode may be greater than or equal to about 5 nm, greater than or equal to about 10 nm, greater than or equal to about 20 nm, greater than or equal to about 30 nm, greater than or equal to about 40 nm, or greater than or equal to about 50 nm. For example, the thickness of the electrode may be less than or equal to about 100 micrometers (μm), less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, or less than or equal to about 100 nm.

The method of forming the electrode is not particularly limited, and can be appropriately selected taking into consideration an electrode material. In one implementation, the electrode can be formed by deposition, coating, or a combination thereof, but is not limited thereto.

The light emitting layer 3, or 30, may be disposed between the first electrode 1 and the second electrode 5 (e.g., the anode 10 and the cathode 50). The light emitting layer may include a semiconductor nanoparticle (e.g., a plurality of semiconductor nanoparticles) such as a blue light emitting nanoparticle, a red light emitting nanoparticle, or a green light emitting nanoparticle. The light emitting layer may include one or more (e.g., 2 or more, or 3 or more, and 10 or less) monolayers of the semiconductor nanoparticle.

The light emitting layer may be patterned (not shown). In an embodiment, the patterned light emitting layer may include a blue light emitting layer disposed in the blue pixel. In an embodiment, the light emitting layer may further include a red light emitting layer disposed in the red pixel or a green light emitting layer disposed in the green pixel. In an embodiment, the light emitting layer may include a red light emitting layer disposed in the red pixel and a green light emitting layer disposed in the green pixel. Each of the (e.g., red, green, or blue) light emitting layers may be (e.g., optically) separated from an adjacent light emitting layer by a partition wall. In an embodiment, partition walls such as black matrices may be disposed between the red light emitting layer, the green light emitting layer, and the blue light emitting layer. The red light emitting layer, the green light emitting layer, and the blue light emitting layer may be optically isolated from each other.

In an embodiment, the light emitting layer 3, 30, or the semiconductor nanoparticle may not include cadmium. In an embodiment, the light emitting layer 3, 30, or the semiconductor nanoparticle may not include mercury, lead, or a combination thereof.

In an embodiment, the semiconductor nanoparticle may have a core-shell structure. In an embodiment, the semiconductor nanoparticle or the core-shell structure may include a core including a first semiconductor nanocrystal and a shell disposed on the core and including a second semiconductor nanocrystal which has a composition different from that of the first semiconductor nanocrystal.

The semiconductor nanoparticle (or the first semiconductor nanocrystal, the second semiconductor nanocrystal, or a combination thereof) may include a Group II-VI compound, a Group III-V compound, a Group IV-VI compound, a Group IV element or compound, a Group I-III-VI compound, a Group II-III-VI compound, a Group I-II-IV-VI compound, or a combination thereof. In an embodiment, the light emitting layer or the semiconductor nanoparticle (e.g., the first semiconductor nanocrystal, or the second semiconductor nanocrystal) may not include cadmium. In an embodiment, the light emitting layer, or the semiconductor nanoparticle (e.g., the first semiconductor nanocrystal or the second semiconductor nanocrystal) may not include lead. In an embodiment, the light emitting layer, or the semiconductor nanoparticle (e.g., the first semiconductor nanocrystal, or the second semiconductor nanocrystal) may not include a combination of lead and cadmium.

The Group II-VI compound may be a binary element compound such as ZnS, ZnSe, ZnTe, ZnO, HgS, HgSe, HgTe, MgSe, MgS, or a combination thereof; a ternary element compound such as ZnSeS, ZnSeTe, ZnSTe, HgSeS, HgSeTe, HgSTe, HgZnS, HgZnSe, HgZnTe, MgZnSe, MgZnS, or a combination thereof; a quaternary element compound such as HgZnTeS, HgZnSeS, HgZnSeTe, HgZnSTe, or a combination thereof; or a combination thereof. The Group II-VI compound may further include a Group III metal.

The Group III-V compound may be a binary element compound such as GaN, GaP, GaAs, GaSb, AlN, AlP, AlAs, AlSb, InN, InP, InAs, InSb, or a combination thereof; a ternary element compound such as GaNP, GaNAs, GaNSb, GaPAs, GaPSb, AlNP, AlNAs, AlNSb, AlPAs, AlPSb, InNP, InNAs, InNSb, InPAs, InPSb, or a combination thereof; a quaternary element compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a combination thereof; or a combination thereof. The Group III-V compound may further include a Group II metal (e.g., InZnP).

The Group IV-VI compound may be a binary element compound such as SnS, SnSe, SnTe, PbS, PbSe, PbTe, or a combination thereof; a ternary element compound such as SnSeS, SnSeTe, SnSTe, PbSeS, PbSeTe, PbSTe, SnPbS, SnPbSe, SnPbTe, or a combination thereof; a quaternary element compound such as SnPbSSe, SnPbSeTe, SnPbSTe, or a combination thereof; or a combination thereof.

Examples of the Group I-III-VI compound may be CuInSe₂, CuInS₂, CuInGaSe, and CuInGaS, but are not limited thereto. Examples of the Group I-III-VI compound may include a ternary element compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAIO₂ or a combination thereof; a quaternary element compound such as AgInGaS₂, AgInGaSe₂; or a combination thereof.

Examples of the Group I-II-IV-VI compound may be CuZnSnSe, and CuZnSnS, but are not limited thereto.

The Group IV element or compound may include a single element (elementary substance) such as Si, Ge, or a combination thereof; a binary element compound such as SiC, SiGe, or a combination thereof; or a combination thereof.

Each element included in a multi-element compound such as a binary element compound, a ternary element compound, or a quaternary element compound may be present in the particle at a uniform concentration or at a non-uniform concentration. For example, the chemical formula described above means the types of elements included in the compound, and the ratio among the elements in the compound may be different. For example, the chemical formula “AgInGaS₂” may include AgInₓGa₁₋ₓS₂ (x is a real number of greater than 0 and less than or equal to 1), but is not limited thereto.

In an embodiment, the first semiconductor nanocrystal may include a metal including indium, zinc, or a combination thereof, and a non-metal including phosphorus, selenium, tellurium, sulfur, or a combination thereof. In an embodiment, the second semiconductor nanocrystal may include a metal including indium, zinc, or a combination thereof, and a non-metal element including phosphorus, selenium, tellurium, sulfur, or a combination thereof.

In an embodiment, the first semiconductor nanocrystal may include InP, InZnP, ZnSe, ZnSeS, ZnSeTe, or a combination thereof; the second semiconductor nanocrystal may include ZnSe, ZnSeS, ZnS, ZnTeSe, or a combination thereof. In an embodiment, the shell may include zinc, sulfur, and optionally selenium for example in the outermost layer.

In an embodiment, the semiconductor nanoparticle may emit blue or green light and may include a core including ZnSeTe, ZnSe, or a combination thereof, and a shell including a zinc chalcogenide (e.g., ZnS, ZnSe, ZnSeS, or a combination thereof). An amount of sulfur in the shell may increase or decrease in a radial direction (from the core toward the surface), e.g., the amount of sulfur may have a concentration gradient wherein the concentration of sulfur varies radially (e.g., decreases or increases in a direction toward the core).

In an embodiment, the semiconductor nanoparticle may emit red or green light, the core may include InP, InZnP, or a combination thereof, and the shell may include a Group II metal including zinc and a non-metal including sulfur, selenium, or a combination thereof.

In an embodiment, the semiconductor nanoparticle may have a core-shell structure, and on the interface between the core and the shell, an alloyed interlayer may be present or may not be present. The alloyed interlayer may include a homogeneous alloy or may have a concentration gradient. The gradient alloy may have a concentration gradient wherein the concentration of an element of the shell varies radially (e.g., decreases or increases in a direction toward the core).

In an embodiment, the shell may have a composition that varies in a radial direction. In an embodiment, the shell may be a multilayered shell including two or more layers. In a multilayered shell, adjacent two layers may have different compositions from each other. In a multilayered shell, a, e.g., at least one, layer may independently include a semiconductor nanocrystal having a single composition. In a multilayered shell, a, e.g., at least one, layer may independently have an alloyed semiconductor nanocrystal. In a multilayered shell, a, e.g., at least one, layer may have a concentration gradient that varies radially in terms of a composition of a semiconductor nanocrystal.

In an embodiment, in the semiconductor nanoparticle having a core-shell structure, a shell material may have a bandgap energy that is larger, e.g., greater, than that of the core. The materials of the shell may have a bandgap energy that is smaller, e.g., less, than that of the core. In the case of a multilayered shell, the bandgap energy of the outermost layer material of the shell may be greater than the bandgap energies of the core and the inner layer material of the shell (layers that are closer to the core). In the case of a multilayered shell, a semiconductor nanocrystal of each layer is selected to have an appropriate bandgap, thereby effectively showing, e.g., exhibiting, a quantum confinement effect.

The semiconductor nanoparticle according to an embodiment may include, for example, an organic ligand which is bonded or coordinated to a surface thereof.

An absorption or emission wavelength of the semiconductor nanoparticle may be controlled by adjusting the compositions, sizes, or a combination thereof, of the semiconductor nanoparticle. The semiconductor nanoparticle included in the light emitting layer 3, or 30, may be configured to emit light of a desired color. The semiconductor nanoparticle may include a blue light emitting semiconductor nanoparticle, a green light emitting semiconductor nanoparticle, or a red light emitting semiconductor nanoparticle.

In an embodiment, a peak emission wavelength of the semiconductor nanoparticle or a light emission layer (or the light emitted from the electroluminescent device) may be in a wavelength range of from ultraviolet to infrared. In an embodiment, the peak emission wavelength of the semiconductor nanoparticle or the light emitting layer (or the light emitted from the electroluminescent device) may be greater than or equal to about 300 nm, greater than or equal to about 500 nm, greater than or equal to about 510 nm, greater than or equal to about 520 nm, greater than or equal to about 530 nm, greater than or equal to about 540 nm, greater than or equal to about 550 nm, greater than or equal to about 560 nm, greater than or equal to about 570 nm, greater than or equal to about 580 nm, greater than or equal to about 590 nm, greater than or equal to about 600 nm, or greater than or equal to about 610 nm. The peak emission wavelength may be less than or equal to about 900 nm, less than or equal to about 800 nm, less than or equal to about 650 nm, less than or equal to about 640 nm, less than or equal to about 630 nm, less than or equal to about 620 nm, less than or equal to about 610 nm, less than or equal to about 600 nm, less than or equal to about 590 nm, less than or equal to about 580 nm, less than or equal to about 570 nm, less than or equal to about 560 nm, less than or equal to about 550 nm, or less than or equal to about 540 nm. The peak emission wavelength may be from about 500 nm to about 650 nm.

The semiconductor nanoparticle, the light emitting layer, or the electroluminescent device may emit green light (for example, on an application of a voltage or irradiation with light) and a peak emission wavelength thereof may be in the range of greater than or equal to about 500 nm (for example, greater than or equal to about 510 nm, or greater than or equal to about 515 nm) and less than or equal to about 560 nm, for example, less than or equal to about 540 nm, or less than or equal to about 530 nm.

The semiconductor nanoparticle, the light emitting layer, or the electroluminescent device may emit red light (for example, on an application of voltage or irradiation with light), and a peak emission wavelength thereof may be in the range of greater than or equal to about 600 nm, for example, greater than or equal to about 610 nm and less than or equal to about 650 nm, or less than or equal to about 640 nm.

The semiconductor nanoparticle, the light emitting layer, or the electroluminescent device may emit blue light (for example, on an application of voltage or irradiation with light), and a peak emission wavelength thereof may be greater than or equal to about 430 nm (for example, greater than or equal to about 450 nm, greater than or equal to about 455 nm, greater than or equal to about 460 nm, greater than or equal to about 465 nm) and less than or equal to about 480 nm (for example, less than or equal to about 475 nm, less than or equal to about 470 nm, or less than or equal to about 465 nm).

In an embodiment, the semiconductor nanoparticle, the light emitting layer, or the electroluminescent device may exhibit a luminescent spectrum (e.g., photo- or electro-luminescent spectrum) with a relatively narrow full width at half maximum. In an embodiment, in the photo- or electro-luminescent spectrum, the semiconductor nanoparticle, the light emitting layer, or the electroluminescent device may exhibit a full width at half maximum of less than or equal to about 45 nm, less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, or less than or equal to about 35 nm. The full width at half maximum may be greater than or equal to about 10 nm, greater than or equal to about 15 nm, greater than or equal to about 20 nm, or greater than or equal to about 25 nm.

The semiconductor nanoparticle may exhibit (or may be configured to exhibit) a quantum efficiency (or quantum yield) of greater than or equal to about 10%, for example, greater than or equal to about 30%, greater than or equal to about 50%, greater than or equal to about 60%, greater than or equal to about 70%, greater than or equal to about 80%, greater than or equal to about 90%, or about 100%.

The semiconductor nanoparticle may have a size (or an average size, hereinafter, can be simply referred to as “size”) of greater than or equal to about 1 nm and less than or equal to about 100 nm. The size may be a diameter or equivalent diameter converted by assuming a spherical shape from an electron microscope image when not spherical. The size may be calculated by using a result of an inductively coupled plasma atomic emission spectroscopy (ICP-AES) analysis. In an embodiment, the semiconductor nanoparticle may have a size of from about 1 nm to about 50 nm, for example, from about 2 nm (or about 3 nm) to about 35 nm. In an embodiment, a size (or an average size) of the semiconductor nanoparticle may be greater than or equal to about 3 nm, greater than or equal to about 4 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, or greater than or equal to about 12 nm. In an embodiment, a size (or an average size) of the semiconductor nanoparticle may be less than or equal to about 50 nm, less than or equal to about 40 nm, less than or equal to about 30 nm, less than or equal to about 25 nm, less than or equal to about 20 nm, less than or equal to about 19 nm, less than or equal to about 18 nm, less than or equal to about 17 nm, less than or equal to about 16 nm, less than or equal to about 15 nm, less than or equal to about 14 nm, less than or equal to about 13 nm, or less than or equal to about 12 nm.

A shape of the semiconductor nanoparticle or the semiconductor nanostructure is not particularly limited. For example, the shape of the semiconductor nanoparticle may include, but is not limited to, a sphere, a polyhedron, a pyramid, a multi-pod shape, a hexahedron, a cube, a cuboid, a nanotube, a nanorod, a nanowire, a nanosheet, or a combination thereof.

The semiconductor nanoparticle may be prepared in an appropriate method. The semiconductor nanoparticle may be prepared for example by a chemical wet method wherein a nanocrystal particle may grow by a reaction between precursors in a reaction system including an organic solvent and an organic ligand. The organic ligand or the organic solvent may coordinate with or to a surface of the semiconductor nanocrystal to control the growth thereof.

In an embodiment, for example, the method of preparing the semiconductor nanoparticle having a core/shell structure may include obtaining the core; reacting a first shell precursor including a metal (e.g., zinc) and a second shell precursor including a non-metal element (e.g., selenium, sulfur, or a combination thereof) in the presence of the core in a reaction medium including an organic ligand and an organic solvent at a reaction temperature (e.g., of greater than or equal to about 180° C., greater than or equal to about 200° C., greater than or equal to about 240° C., or greater than or equal to about 280° C. and less than or equal to about 360° C., less than or equal to about 340° C., or less than or equal to about 320° C.) to form a shell including a second semiconductor nanocrystal on a core including a first semiconductor nanocrystal. The method may further include separating a core from a reaction system producing the same and dispersing the core in an organic solvent to obtain a core solution.

In an embodiment, in order to form the shell, a solvent and optionally, the first shell precursor and a ligand compound may be heated at a predetermined temperature (e.g., greater than or equal to about 100° C.) under vacuum (also referred to herein as vacuum-treated) and then, after introducing an inert gas into the reaction vessel, the mixture may be heat-treated again at a predetermined temperature (e.g., greater than or equal to 100° C.). Then, the core and the second shell precursor may be added to the mixture and heated at a reaction temperature. The shell precursors may be added at different ratios during a reaction time simultaneously or sequentially.

In the semiconductor nanoparticle of an embodiment, the core may be prepared in an appropriate manner. In an embodiment, the organic solvent may include a C6 to C22 primary amine such as a hexadecylamine, a C6 to C22 secondary amine such as dioctylamine, a C6 to C40 tertiary amine such as a trioctyl amine, a nitrogen-containing heterocyclic compound such as pyridine, a C6 to C40 olefin such as octadecene, a C6 to C40 aliphatic hydrocarbon such as hexadecane, octadecane, or squalane, an aromatic hydrocarbon substituted with a C6 to C30 alkyl group such as phenyldodecane, phenyltetradecane, or phenyl hexadecane, a primary, secondary, or tertiary phosphine (e.g., trioctyl phosphine) substituted with a, e.g., at least one (e.g., 1, 2, or 3), C6 to C22 alkyl group, a phosphine oxide (e.g., trioctylphosphine oxide) substituted with a (e.g., 1, 2, or 3) C6 to C22 alkyl group, a C12 to C22 aromatic ether such as phenyl ether or benzyl ether, or a combination thereof. A combination including more than one type of organic solvent may be used.

The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH or a combination thereof. Herein, R and R′ are each independently a substituted or unsubstituted, C3 or greater, C6 or greater, or C10 or greater and C40 or less, C35 or less, or C25 or less, aliphatic hydrocarbon group (e.g., alkyl, alkenyl, alkynyl, etc.), a substituted or unsubstituted C6 to C40 aromatic hydrocarbon group (e.g., aryl group), or a combination thereof. In an embodiment, at least two different organic ligands may be used.

Examples of the organic ligand may be a thiol compound such as methane thiol, ethane thiol, propane thiol, butane thiol, pentane thiol, hexane thiol, octane thiol, dodecane thiol, hexadecane thiol, octadecane thiol, benzyl thiol, and the like; amines such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, trioctylamine, and the like; a carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, myristic acid, stearic acid, lauric acid, benzoic acid, and the like; a phosphine compound such as methyl phosphine, ethyl phosphine, propyl phosphine, butyl phosphine, pentyl phosphine, octylphosphine, dioctyl phosphine, tributylphosphine, trioctylphosphine, and the like; a phosphine oxide compound thereof such as methyl phosphine oxide, ethyl phosphine oxide, propyl phosphine oxide, butyl phosphine oxide, pentyl phosphineoxide, tributylphosphineoxide, octylphosphine oxide, dioctyl phosphineoxide, trioctylphosphineoxide, and the like; diphenyl phosphine, triphenyl phosphine compound (DPP) or an oxide compound thereof; C5 to C20 alkyl phosphinic acid such as hexylphosphinic acid, octylphosphinic acid, dodecanephosphinic acid, tetradecanephosphinic acid, hexadecanephosphinic acid, octadecanephosphinic acid; C5 to C20 alkyl phosphonic acid; and the like, but is not limited thereof.

The semiconductor nanoparticle may be recovered by a process of pouring a non-solvent into a mixture including the semiconductor nanoparticle and subjecting the mixture to a centrifugation in order to remove excess organic substance that is not coordinated on the surface from them. For example, in an embodiment, after completing the reaction (for the formation of the core or for the formation of the shell), a non-solvent may be added to a reaction mixture and the semiconductor nanoparticle coordinated with the ligand compound may be separated therefrom. The non-solvent may be a polar solvent that is miscible with the solvent used in the core formation reactions, shell formation reaction, or a combination thereof, and is not capable of dispersing the prepared semiconductor nanoparticles. The non-solvent may be selected depending on the solvent used in the reaction and may include, for example, acetone, ethanol, butanol, isopropanol, ethanediol, water, tetrahydrofuran (THF), dimethylsulfoxide (DMSO), diethylether, formaldehyde, acetaldehyde, ethylene glycol, a solvent having a similar solubility parameter to the foregoing non-solvents, or a combination thereof. The semiconductor nanoparticles may be separated through centrifugation, sedimentation, or chromatography. The separated semiconductor nanoparticles may be washed with a washing solvent, if desired. The washing solvent has no particular limit and may have a similar solubility parameter to that of the ligand and may, for example, include hexane, heptane, octane, chloroform, toluene, benzene, and the like.

The semiconductor nanoparticles of an embodiment may be non-dispersible or insoluble in water, the aforementioned non-solvent, or a combination thereof. The semiconductor nanoparticles of an embodiment may be dispersed in the aforementioned organic solvent. In an embodiment, the aforementioned semiconductor nanoparticles may be dispersed in a C6 to C40 aliphatic hydrocarbon, a substituted or unsubstituted C6 to C40 aromatic hydrocarbon, or a combination thereof.

In the electroluminescent device or the display device of an embodiment, a thickness of the light emitting layer may be appropriately selected. In an embodiment, the light emitting layer may include a monolayer of nanoparticles. In an embodiment, the light emitting layer may include one or more, for example, two or more, three or more, or four or more and 20 or less, 10 or less, 9 or less, 8 or less, 7 or less, or 6 or less monolayers of semiconductor nanoparticles. The light emitting layer may have a thickness of greater than or equal to about 5 nm, for example, greater than or equal to about 10 nm, greater than or equal to about 20 nm, or greater than or equal to about 30 nm and less than or equal to about 200 nm, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm. The light emitting layer may have a thickness of, for example, about 10 nm to about 150 nm, about 20 nm to about 100 nm, or about 30 nm to about 50 nm.

In an embodiment, the disposing (e.g., forming) of the light emitting layer 3 including the semiconductor nanoparticle may be performed by providing a composition including a semiconductor nanoparticle and an organic solvent and applying or depositing the same on a substrate (e.g., an electrode) or a charge auxiliary layer (e.g., a hole auxiliary layer or electron auxiliary layer) in an appropriate manner (e.g., by spin coating, inkjet printing, etc.). The forming of the light emitting layer may further include heat-treating the coated or deposited semiconductor nanoparticle layer. The heat-treating temperature is not particularly limited, and it can be appropriately selected taking into consideration the boiling point of the organic solvent. For example, the heat treatment temperature may be greater than or equal to about 60° C., or greater than or equal to about 70° C., and less than or equal to about 250° C., or less than or equal to about 180° C. A type of the organic solvent for the coating liquid is not particularly limited and may be selected appropriately. In an embodiment, the organic solvent may include a substituted or unsubstituted aliphatic hydrocarbon organic solvent, a substituted or unsubstituted aromatic hydrocarbon solvent, a substituted or unsubstituted alicyclic hydrocarbon solvent, an acetate solvent, or a combination thereof.

In an embodiment, the light emitting layer may be a single layer or a multi-layered structure having at least two layers. In the multi-layered structure, adjacent layers (e.g., a first light emitting layer and a second light emitting layer) may be configured to emit a first light (e.g., green light, blue light, or red light). In the multi-layered structure, adjacent layers (e.g., a first light emitting layer and a second light emitting layer) may have the same or different composition, ligands, or a combination thereof. In an embodiment, the (multi-layered) light emitting layer may have a halogen amount that varies (increase or decrease) in a thickness direction. In an embodiment, in the (multi-layered) light emitting layer, the amount of the halogen may increase in a direction toward the electron auxiliary layer. In the (multi-layered) light emitting layer, an amount, or a content of an organic ligand may decrease in the direction toward the electron auxiliary layer. In the (multi-layered) light emitting layer, the amount, or the content of the organic ligand may increase in the direction toward the electron auxiliary layer.

In an embodiment, the light emitting layer may include a first light emitting layer including a first semiconductor nanoparticle and a second light emitting layer including a second semiconductor nanoparticle, wherein the first semiconductor nanoparticle has a halogen (e.g., chlorine) exchanged surface and the second light emitting layer has a greater amount of an organic ligand than the first light emitting layer. A halogen (e.g., chlorine) amount and an organic ligand amount of the light emitting layer may be controlled with an appropriate manner (e.g., a post treatment for the formed layer). In an embodiment, a thin film of the semiconductor nanoparticles having an organic ligand (e.g., having a carboxylic acid group) is formed, which is then treated with a solution including a metal halide (e.g., a zinc halide such as a zinc chloride in alcohol solvent) to control (decrease) an amount of the organic ligand of the semiconductor nanoparticles in the thin film. The treated thin film may have an increased halogen amount, showing, e.g., exhibiting, a changed property (e.g., solubility) with respect to an organic solvent, and it may be possible to form a layer of semiconductor nanoparticles having a different amount of an organic ligand (e.g., a halogen treated semiconductor nanoparticle or a semiconductor nanoparticle with a ligand having a carboxylic acid group) on the treated thin film, subsequently.

An electron auxiliary layer 4, or 40, may be disposed on the light emitting layer 3, or 30, for example, between the light emitting layer and the second electrode 5, or 50. In the electron auxiliary layer 4, or 40, transporting, injecting, or transporting and injecting of electrons may occur. The electron auxiliary layer 4, or 40, includes an electron transport layer (ETL). The electron auxiliary layer 4, or 40, may further include an electron injection layer, a hole blocking layer, or a combination thereof. The electron injection layer may be disposed between the electron transport layer and the second electrode, the hole blocking layer may be disposed between the electron transport layer and the light emitting layer, but they are not limited thereto. The electron transport layer may be adjacent to (e.g., directly adjacent to, or directly disposed on) the light emitting layer. In an embodiment, the light emitting layer 3, or 30, may contact the electron transport layer.

The electron transport layer includes a zinc oxide nanoparticle (e.g., a plurality of zinc oxide nanoparticles). The zinc oxide nanoparticle includes a first metal different from zinc and an alkali metal. The first metal may include an alkaline earth metal (e.g., magnesium, calcium, barium, strontium, or a combination thereof), zirconium (Zr), tungsten (W), titanium (Ti), yttrium (Y), aluminum (Al), gallium (Ga), indium (In), tin (Sn), cobalt (Co), vanadium (V), or a combination thereof. The first metal may include an alkaline earth metal and the first metal may further include or may not include zirconium (Zr), tungsten (W), titanium (Ti), yttrium (Y), aluminum (Al), gallium (Ga), indium (In), tin (Sn), cobalt (Co), vanadium (V), or a combination thereof. The alkali metal may include sodium, potassium, rubidium, cesium, francium, or a combination thereof. The alkali metal may include or may not include lithium. The alkali metal may include potassium, rubidium, cesium, or a combination thereof. In an embodiment, the electroluminescent device may exhibit increased electroluminescence (EQE, etc.), for example, by having the features described herein.

An electron auxiliary layer based on a zinc oxide nanoparticle may be provided for a cadmium-based (i.e., cadmium-containing) QD-LED. However, the present inventors have found that despite the use of the electron auxiliary layer based on the zinc oxide nanoparticles, there may be a technological limit in improving both an electroluminescent property and life-span simultaneously, in the case of an electroluminescent device including a cadmium-free semiconductor nanoparticle that is configured to emit light of a desired wavelength (e.g., blue light) in a light emitting layer.

Without wishing to be bound by any theory, it is believed that in QD-LEDs with a light emitting layer containing non-cadmium-based semiconductor nanoparticles (for example, a blue-light emitting semiconductor nanoparticle containing a zinc chalcogenide core), a charge imbalance between the holes moving through the hole auxiliary layer (e.g., a HTL) and the electrons moving through a zinc oxide nanoparticle-based ETL may occur, and the charge imbalance may lead to a decrease in an electroluminescence property (e.g., a maximum external quantum efficiency or a maximum luminance) of the light emitting device or deterioration of the device.

Surprisingly, the present inventors have found that an electroluminescent device of an embodiment including a zinc oxide nanoparticle described herein in an electron transport layer may exhibit improved optical properties together with increased lifespan. The zinc oxide nanoparticle may be prepared by a method described herein. In an embodiment, a synthesis of the zinc oxide nanoparticle involves a use of an inorganic base or a mixture of organic and inorganic bases (e.g., as a reducing agent).

The zinc metal oxide nanoparticle included in the electron transport layer may be synthesized through a sol-gel process or a solution-precipitation process in a bottom-up synthesis manner. Accordingly, the zinc oxide nanoparticle obtained thereby may include an organic material derived from a reagent included in a reaction system, such as a precursor, for example, as a particle surface stabilization ligand, but it may also include a surface defect. Without wishing to be bound by any theory, it is believed that a surface property of the prepared zinc oxide nanoparticle may have an effect on a device performance or its property. For example, a presence of the surface defect may cause, for example, a decrease in an efficiency or a degradation of the electron transport layer.

Without wishing to be bound by any theory, it is also believed that in the synthesis of zinc oxide nanoparticle, a basic reducing agent may reduce various chemical species (for example, RO-M-RO, HO-M-OH, M(OH)x, or MO₁₋ₓ(CH₃CO₂)₂ₓ, wherein M is zinc, or alkaline earth metal and R is for example a hydrocarbon moiety such as an alkyl group) that are derived from the metal precursors (e.g., a zinc carboxylate, an alkaline earth metal carboxylate, etc.) into a metal hydroxide (e.g., Zn(OH)ₓ), and the formed Zn(OH)ₓ may go through a reaction (e.g., a decomposition reaction), resulting in a nucleation and a growth of a zinc oxide nanoparticle. Surprisingly, the present inventors have found that during the synthesis of the zinc oxide nanoparticle, an inorganic base and optionally an organic base may be used as a basic reducing agent according to the method described herein, and the production and decomposition kinetics of Zn(OH)ₓ can be controlled to provide the zinc oxide nanoparticle having the features described herein. The zinc oxide nanoparticle having such features may be able to contribute to the improvement of the electroluminescent device of an embodiment. In addition, the present inventors have found that the electron transport layer containing the zinc metal oxide nanoparticle thus prepared may be included in an electroluminescent device including, for example, a non-cadmium semiconductor nanoparticle-based (i.e., -containing) emission layer, making it possible for the device to exhibit the desired level of electroluminescence properties together with an extended lifespan.

In an embodiment, the zinc oxide nanoparticle may be prepared by a method that includes admixing a first solution including a zinc precursor and a first metal precursor in a solvent (e.g., an organic solvent or a first organic solvent) with a second base and optionally a first base to form the zinc oxide nanoparticle.

The method of an embodiment may further include dissolving the zinc precursor and the first metal precursor in the solvent to prepare the first solution.

The admixing may include conducting a reaction wherein the first metal precursor, the zinc precursor, the second base (inorganic base), and optionally the first base (organic base) are involved, whereby the zinc oxide nanoparticle may be formed.

In the method of an embodiment, the first base may include an organic base (an organic salt compound) containing a C1 to C50 (C1-C12, C2-C9, C3-C8, C4-C5) organic group (e.g., an C1-50, C1-C12, C2-C9, C3-C8, C4-C5 aliphatic hydrocarbon group such as an alkyl group), and the second base may include an inorganic base (an inorganic salt compound) including an alkali metal.

The zinc precursor may include an organic compound including zinc, and the first metal precursor may include an organic compound including a first metal. Details of the first metal and the alkali metal are the same as described herein. In an embodiment, the first metal may include magnesium. In an embodiment, the first metal may be magnesium.

The first solution may include or may not include a C1 to C12 aliphatic amine (e.g., an alkyl amine such as butyl amine), an aromatic amine having a benzene ring, or a combination thereof. The aliphatic/aromatic amine may be a primary amine, a secondary amine, or a tertiary amine. The aliphatic/aromatic amine may include an alcoholic amine. The aliphatic/aromatic amine may be butylamine, ethylamine, hexylamine, hexamethylenediamine, aniline, ethanolamine, or a combination thereof.

The zinc precursor and the first metal precursor may include a carboxylate moiety (for example, an acetate group).

The zinc precursor may include a zinc carboxylate such as zinc acetate, or the like; zinc acetylacetonate; a zinc halide such as a zinc chloride, a zinc bromide, a zinc iodide, a zinc fluoride, or the like; a zinc nitrate; a zinc oxide; or a combination thereof. The first metal (for example, magnesium) precursor may include a carboxylate compound (e.g., an acetate compound), an acetylacetonate compound, a halide, a nitride, an oxide, or a combination thereof. In an embodiment, the first metal precursor may include a magnesium carboxylate (e.g., a magnesium acetate), a magnesium acetylacetonate, a magnesium halide (e.g., a magnesium chloride, a magnesium bromide, a magnesium fluoride, a magnesium iodide), a magnesium nitrate, a magnesium oxide, or a combination thereof.

The (organic) solvent may include a C1 to C10 alcohol solvent (for example, methanol, ethanol, propanol, isopropanol, butanol, isobutanol, pentanol, isopentanol, or a combination thereof), a sulfoxide solvent (e.g., a dimethyl sulfoxide), a C3 to C15 hydrocarbon solvent (an aliphatic solvent, an aromatic solvent, an alicyclic solvent, or an alicyclic compound obtained from a hydrogen addition to an aromatic hydrocarbon) or a combination thereof. The hydrocarbon solvent may include cyclohexane, hexane, heptane, nonane, octane, or a combination thereof. The solvent may include a first organic solvent, and optionally a second organic solvent capable of mixing with the first organic solvent and water. The first organic solvent may include an organic sulfur solvent such as dimethyl sulfoxide. The second organic solvent may contain a C1 to C10 alcohol.

The first base may include a substituted or unsubstituted C1-C50 (e.g., C2-C40, C3-C30, C4-C25, C5-C20, C6-C15, C7-C14, C8-C12, C9-C11, or a combination thereof) aliphatic hydrocarbon group. The number of aliphatic hydrocarbon group may be 1, 2, 3, or 4. The first base may include a quaternary ammonium salt compound. The first base may include a tetraalkylammonium hydroxide (e.g., a tetra(C1-C6 alkyl) ammonium hydroxide, such as a tetramethylammonium hydroxide, tetraethylammonium hydroxide a diethyldimethylammonium hydroxide, a dimethyldipropylammonium hydroxide, or a combination thereof).

The second base may include an alkali metal hydroxide (e.g., a lithium hydroxide, a sodium hydroxide, a potassium hydroxide, a cesium hydroxide, a rubidium hydroxide, a francium hydroxide, or a combination thereof).

The second base may include at least one or at least two alkali metal hydroxides. The second base may include or may not include a lithium hydroxide. In an embodiment, the second base may include a sodium hydroxide, a potassium hydroxide, a cesium hydroxide, a rubidium hydroxide, or a combination thereof. The second base may include or may not include a lithium hydroxide, a sodium hydroxide, or a combination thereof. In an embodiment, the second base may include a potassium hydroxide, a cesium hydroxide, a rubidium hydroxide, or a combination thereof. In an embodiment, the second base may be used alone or may be used together with the first base. The zinc oxide nanoparticle prepared by the method descried herein, for example, may be included in the electroluminescent device (for example in an electron transport layer) to exhibit relatively improved device efficiency (EQE), relatively improved particle dispersibility, or both.

In an embodiment, the first base and the second base may be used together, and a mole ratio between the first base and the second base (i.e., the first base:the second base) may be from about 1:0.1 to about 1:10, from about 1:0.3 to about 1:3, from about 1:0.5 to about 1:27, from about 1:0.8 to about 1:1.5, from about 1:0.83 to about 1:1.2, from about 1:0.9 to about 1:1.3, from about 1:1 to about 1:1.25, or a combination thereof.

In an embodiment, a mole ratio of the second base to the first base may be (the second base:the first base) may be from about 1:0 to about 1:10, from about 1:0.05 to about 1:5, from about 1:0.12 to about 1:4.5, from about 1:0.1 to about 1:3, from about 1:0.5 to about 1:2.7, from about 1:0.65 to about 1:2.5, from about 1:0.8 to about 1:1.5, from about 1:0.8 to about 1:1.3, from about 1:0.9 to about 1:1.27, from about 1:0.95 to about 1:1.2, from about 1:1 to about 1:1.25, from about 1:1.05 to about 1:1.24, or a combination thereof.

In an embodiment, a mole ratio of a sum of the zinc precursor and the first precursor with respect to a sum of the first base and the second baes (the sum of metal precursors:the sum of the bases) may be from about 1:0.5 to about 1:5, from about 1:0.6 to about 1:4, from about 1:0.7 to about 1:3, from about 1:0.8 to about 1:2.5, from about 1:0.9 to about 1:2, from about 1:1 to about 1:1.5, from about 1:1.1 to about 1:1.48, from about 1:1.21 to about 1:1.45, from about 1:1.35 to about 1:1.2, or a combination thereof.

The mole ratio between the zinc precursor and the first metal precursor may be appropriately selected taking into consideration a desired composition of the zinc oxide nanoparticle. In an embodiment, the mole amount of the first metal precursor may be, per one mole of the zinc precursor, from about 0.1 mole to about 1.5 moles, from about 0.2 mole to about 1 mole, from about 0.3 mole to about 0.9 mole, from about 0.4 mole to about 0.8 mole, from about 0.5 mole to about 0.7 mole, or a combination thereof.

In the method, the first base or the second base may be dissolved in the solvent (e.g., a second organic solvent such as an alcohol solvent) and added (mixed) with the first solution. In an embodiment, the first base and the second base may be added separately or as a mixture. The method may include or may not include adding an organic acid (for example, acetic acid) or an inorganic acid to a reaction system before or after the first base is added, or before or after the second base is added.

The temperature and time for the reaction can be appropriately adjusted. The temperature for the reaction may be greater than or equal to about 0° C., for example, greater than or equal to about 10° C., greater than or equal to about 20° C., greater than or equal to about 25° C., greater than or equal to about 30° C., greater than or equal to about 35° C., greater than or equal to about 40° C., or greater than or equal to about 45° C. The temperature may be less than or equal to about 100° C., less than or equal to about 80° C., less than or equal to about 70° C., less than or equal to about 65° C., less than or equal to about 60° C., less than or equal to about 55° C., less than or equal to about 50° C., or less than or equal to about 42° C. The time for the reaction may be from about 10 minutes to 300 minutes. The reaction time may be greater than or equal to about 20 minutes, greater than or equal to about 40 minutes, greater than or equal to about 50 minutes, greater than or equal to about 70 minutes, greater than or equal to about 90 minutes, greater than or equal to about 110 minutes, greater than or equal to about 120 minutes, greater than or equal to about 130 minutes, or greater than or equal to about and 140 minutes. The reaction time may be less than or equal to about 280 minutes, less than or equal to about 250 minutes, or less than or equal to about 150 minutes.

In the method of an embodiment, for example, to improve dispersibility of the nanoparticles as prepared, the addition of the base may be performed at a predetermined temperature for example, at room temperature, or at a temperature of about 20° C. to about 40° C., or at a temperature of about 25° C. to about 30° C. In the method of an embodiment, for example, to improve the dispersibility of the prepared particles, the reaction may be performed at a temperature of less than or equal to about 60° C., for example, from about 20 to about 35° C.

The zinc oxide nanoparticle obtained by the method may further include the first metal and the alkali metal, and may exhibit an optical property described herein.

In the zinc oxide nanoparticle or the electron transport layer, a mole ratio of the alkali metal to the first metal (e.g., magnesium; or in case where the first metal includes at least two metals, a sum of moles of the at least two metals) may be greater than or equal to about 0.005:1, greater than or equal to about 0.01:1, greater than or equal to about 0.015:1, greater than or equal to about 0.02:1, greater than or equal to about 0.025:1, greater than or equal to about 0.03:1, greater than or equal to about 0.04:1, greater than or equal to about 0.05:1, greater than or equal to about 0.06:1, greater than or equal to about 0.07:1, greater than or equal to about 0.08:1, greater than or equal to about 0.09:1, greater than or equal to about 0.1:1, greater than or equal to about 0.11:1, greater than or equal to about 0.12:1, greater than or equal to about 0.13:1, greater than or equal to about 0.14:1, greater than or equal to about 0.15:1, greater than or equal to about 0.16:1, greater than or equal to about 0.17:1, greater than or equal to about 0.18:1, greater than or equal to about 0.19:1, greater than or equal to about 0.2:1, greater than or equal to about 0.22:1, greater than or equal to about 0.24:1, greater than or equal to about 0.26:1, greater than or equal to about 0.28:1, greater than or equal to about 0.3:1, greater than or equal to about 0.32:1, greater than or equal to about 0.34:1, greater than or equal to about 0.35:1, greater than or equal to about 0.36:1, greater than or equal to about 0.38:1, greater than or equal to about 0.4:1, greater than or equal to about 0.42:1, greater than or equal to about 0.44:1, greater than or equal to about 0.46:1, greater than or equal to about 0.48:1, or greater than or equal to about 0.5:1. In the zinc oxide nanoparticle or the electron transport layer, a mole ratio of the alkali metal to the first metal may be less than or equal to about 2:1, less than or equal to about 1.7:1, less than or equal to about 1.5:1, less than or equal to about 1.3:1, less than or equal to about 1.1:1, less than or equal to about 1:1, less than or equal to about 0.9:1, less than or equal to about 0.77:1, less than or equal to about 0.7:1, less than or equal to about 0.65:1, or less than or equal to about 0.6:1.

In the zinc oxide nanoparticle or the electron transport layer, a mole ratio of the alkali metal (e.g., the sodium, the potassium, the cesium, the rubidium, or the combination thereof) to the zinc may be greater than or equal to about 0.01:1, greater than or equal to about 0.02:1, greater than or equal to about 0.03:1, greater than or equal to about 0.035:1, greater than or equal to about 0.04:1, greater than or equal to about 0.05:1, greater than or equal to about 0.07:1, greater than or equal to about 0.08:1, greater than or equal to about 0.09:1, greater than or equal to about 0.1:1, greater than or equal to about 0.13:1, or greater than or equal to about 0.15:1. In the zinc oxide nanoparticle or the electron transport layer, a mole ratio of the alkali metal with respect to the zinc may be less than or equal to about 0.5:1, less than or equal to about 0.4:1, less than or equal to about 0.3:1, less than or equal to about 0.2:1, less than or equal to about 0.1:1, less than or equal to about 0.08:1, less than or equal to about 0.077:1, less than or equal to about 0.075:1, less than or equal to about 0.06:1, less than or equal to about 0.05:1, less than or equal to about 0.049:1, or less than or equal to about 0.045:1.

In the zinc oxide nanoparticle or the electron transport layer, a mole ratio of a sum of the first metal and the alkali metal with respect to the zinc [(the first metal+the alkali metal):the zinc] may be greater than or equal to about 0.1:1, greater than or equal to about 0.115:1, greater than or equal to about 0.15:1, greater than or equal to about 0.17:1, greater than or equal to about 0.19:1, greater than or equal to about 0.2:1, greater than or equal to about 0.21:1, greater than or equal to about 0.22:1, greater than or equal to about 0.23:1, greater than or equal to about 0.25:1, greater than or equal to about 0.27:1, greater than or equal to about 0.29:1, or greater than or equal to about 0.3:1 and less than or equal to about 1:1, less than or equal to about 0.9:1, less than or equal to about 0.8:1, less than or equal to about 0.7:1, less than or equal to about 0.6:1, less than or equal to about 0.5:1, less than or equal to about 0.4:1, less than or equal to about 0.35:1, less than or equal to about 0.34:1, or less than or equal to about 0.31:1.

In the zinc oxide nanoparticle or the electron transport layer, a mole ratio of the magnesium to the zinc may be less than or equal to about 0.5:1, less than or equal to about 0.45:1, less than or equal to about 0.35:1, less than or equal to about 0.3:1, less than or equal to about 0.25:1, or less than or equal to about 0.2:1. In the zinc oxide nanoparticle, a mole ratio of the magnesium to the zinc may be less than or equal to about 0.01:1, greater than or equal to about 0.03:1, greater than or equal to about 0.05:1, greater than or equal to about 0.07:1, greater than or equal to about 0.09:1, greater than or equal to about 0.1:1, greater than or equal to about 0.12:1, greater than or equal to about 0.14:1, greater than or equal to about 0.16:1, greater than or equal to about 0.18:1, or greater than or equal to about 0.24:1.

In an embodiment, the zinc oxide nanoparticle may have a greater content of the alkali metal in an outer portion of the particle than in an inner portion thereof. In an embodiment, the zinc oxide nanoparticle may have a core-shell structure including a core and an outer layer disposed on the core. The zinc oxide nanoparticle or the core may include Zn₁₋ₓMₓO (where M is Mg, Ca, Zr, W, Li, Ti, Y, Al, or a combination thereof, and 0≤x≤0.5). In the above formula, x may be greater than 0, greater than or equal to about 0.01, greater than or equal to about 0.03, greater than or equal to about 0.05, greater than or equal to about 0.07, greater than or equal to about 0.1, greater than or equal to about 0.13, greater than or equal to about 0.15, greater than or equal to about 0.17, greater than or equal to about 0.2, greater than or equal to about 0.23, or greater than or equal to about 0.25. The x may be less than or equal to about 0.47, less than or equal to about 0.45, less than or equal to about 0.43, less than or equal to about 0.4, less than or equal to about 0.37, less than or equal to about 0.35, or less than or equal to about 0.3. The outer layer of the zinc oxide nanoparticles may include an alkali metal and, optionally, an organic material. In an embodiment, the alkali metal may be present in the zinc oxide nanoparticle or be bonded or adsorbed to a surface of the zinc oxide nanoparticle (for example, to a hydroxyl group on the surface of the particle).

A feature such as the presence of each component in a zinc oxide particle or the electron transport layer or a feature such as a mole ratio between the components may be determined or measured by an appropriate analysis tool (an X-ray photoelectron spectroscopy (XPS), an inductively coupled plasma atomic emission spectroscopy, a scanning or transmission electron microscope energy dispersion spectroscopy, etc.).

In an embodiment, when the zinc oxide nanoparticle or the electron transport layer is analyzed by XPS, a zinc (e.g., Zn2p) peak of the zinc oxide nanoparticle may have its maximum intensity or may appear in a binding energy range of from about 1047 electronvolts (eV) to about 1042 eV (e.g., 1045 eV). In an embodiment, the zinc oxide nanoparticle may exhibit a Zn2p peak that is shifted to a lower binding energy (e.g., by about 0.1 eV) than a Zn2p peak of a zinc oxide nanoparticle prepared using only an organic base (e.g., tetramethylammonium hydroxide, TMAH), thus using the first base and without using the second base. In an embodiment, when the zinc oxide nanoparticle or the electron transport layer is analyzed by XPS, an oxygen (e.g., O1s) peak (e.g., split peaks) of the zinc oxide nanoparticle may have its maximum intensity or may appear in a binding energy range of from about 533 eV to about 526 eV, and an alkali metal-related peak of the zinc oxide nanoparticle, for example, (e.g., Rb3p) that may have its maximum intensity or may appear in a binding energy range of from about 230 eV to about 250 eV, from about 230 eV to about 245 eV, from about 235 eV to about 245 eV, from about 237 eV to about 240 eV, from about 245 eV to about 250 eV, or any combined range. There may be two or more peaks for the alkali metal. In an embodiment, the zinc oxide nanoparticle may exhibit two alkali metal-related peaks present in the binding energy ranges, respectively (e.g., one in a range from about 230 eV to about 245 eV and another in a range of from about 245 eV to about 250 eV). When analyzed by XPS, the zinc oxide nanoparticle or the electron transport layer of an embodiment may show a peak (or at least two peaks) related to an alkali metal (e.g., Rb3d), for example, at 105 eV to 115 eV, or 108 eV to 112 eV. In the XPS analysis, the zinc oxide nanoparticle or the electron transport layer of an embodiment may show a peak or at least two peaks related to an alkali metal (e.g., Cs3d), each within the range of about 735 eV to about 740 eV and about 722 eV to about 728 eV.

The zinc oxide nanoparticle produced according to the method of an embodiment (for example, using a second base and optionally a first base) may exhibit a decomposition pattern in a thermogravimetric analysis, in comparison with a zinc oxide nanoparticle prepared using only an organic base. In comparison with a zinc oxide nanoparticle prepared using only the first base (organic base), the zinc oxide nanoparticle of an embodiment may have a lower maximum peak temperature in a DTG curve (the first derivative of a thermogravimetric analysis curve) for example, in a temperature range of less than or equal to about 330° C., less than or equal to about 325° C., less than or equal to about 320° C., less than or equal to about 315° C., less than or equal to about 310° C., less than or equal to about 305° C., less than or equal to about 300° C., and greater than or equal to about 290° C., or greater than or equal to about 300° C.

Without wishing to be bound by any theory, in an embodiment wherein a mixture of the reducing agents (i.e., the first base and the second base, referred to as “a mixed reducing agent”) is used, an organic moiety (e.g., a cation containing a hydrocarbon group) from the first base and an alkali metal cation from the second base may compete with each other to provide a passivation of an outer surface of a formed nanoparticle (e.g., a passivation of a hydroxyl group present on a surface the formed nanoparticle), and the resulting zinc oxide nanoparticle may have an alkali metal and an organic moiety (e.g., a carbon-containing functional group) on a surface of the nanoparticle.

In an embodiment, in the zinc oxide nanoparticle synthesized in the presence of the mixed reducing agent in the method of an embodiment, a decomposition of the carbon containing functional group, for example, which occurs during a thermogravimetric analysis, may be accelerated at a relatively lower temperature as compared with the case of a zinc oxide nanoparticle prepared using only the first base (for example, TMAH) as a single reducing agent. In an embodiment, the zinc oxide nanoparticle synthesized in the presence of the mixed reducing agent may exhibit a reduced peak intensity of a residue derived from an organic base or no peak that is allocated to a residue derived from an organic base, when analyzed by Fourier transform infrared (FTIR) spectroscopy. Without wishing to be bound by any theory, these results may result from a weak binding of the carbon-containing functional group to a surface of the particle. In an embodiment, the zinc oxide nanoparticle may not exhibit a peak that can be assigned to an amine moiety (e.g., N—CH₃) (e.g., at a wavenumber range of from about 1485 centimeter⁻¹ (cm⁻¹) to about 1490 cm⁻¹, for example about 1488 cm⁻¹ or about 1490 cm⁻¹) in the FTIR spectrum when analyzed by the FTIR spectroscopy. In an embodiment, the zinc oxide nanoparticle may not exhibit a peak that can be assigned to amine at a wavenumber range of about 945 cm⁻¹ to about 950 cm⁻¹ (for example, about 948 cm⁻¹).

Without wishing to be bound by any theory, it is believed that in the method of an embodiment, optionally being used with the first base or an organic base, the metal cation species of the second base (e.g., alkali metal hydroxide) may change a physical property (for example, a surface state or an electrical or optical property such as a feature shown in UV-Vis absorption spectrum) of the zinc oxide nanoparticle thus produced. In other words, it is believed that that using the second base optionally together with the first base in the method of an embodiment may have an effect on a surface property and an electrical/optical property of the formed zinc oxide nanoparticle.

By adopting the feature of the method of an embodiment, the zinc oxide nanoparticle included in the electroluminescent device of an embodiment may have improved passivation for a defect that may otherwise exist on a surface of the particle (e.g., via an additional adsorption of an inorganic substance such as an alkali metal ion and an organic matter) while exhibiting a dispersibility desired for a subsequent manufacturing process of the device. Surprisingly, the present inventors have found that in a particle-based (i.e., particle-containing) electronic auxiliary (transporting) layer, the zinc oxide nanoparticle synthesized by the method described herein may reduce a defect (e.g., a surface defect) derived from a particle and may prevent or suppress a deterioration or a decrease of an electrical property of the electronic auxiliary layer. In addition, as being included in the electron auxiliary layer (e.g., the electron transport layer), the zinc oxide nanoparticle produced in the method of an embodiment may exhibit increased conductivity and a reduce level of a leakage current of the layer.

In an electroluminescent device of an embodiment, an electron auxiliary layer including a zinc oxide nanoparticle may be disposed between the second electrode and the light emitting layer, and as a voltage of 0 volts to 8 volts is applied to the device thus obtained, a current density at 8 volts during a third sweep may be greater than or equal to about 100 milliamperes per square centimeter (mA/cm²), greater than or equal to about 110 mA/cm², greater than or equal to about 120 mA/cm², greater than or equal to about 130 mA/cm², greater than or equal to about 140 mA/cm², greater than or equal to about 150 mA/cm², greater than or equal to about 160 mA/cm², greater than or equal to about 170 mA/cm², greater than or equal to about 180 mA/cm², greater than or equal to about 190 mA/cm², greater than or equal to about 200 mA/cm², greater than or equal to about 210 mA/cm², greater than or equal to about 220 mA/cm², greater than or equal to about 230 mA/cm², greater than or equal to about 239 mA/cm², greater than or equal to about 240 mA/cm², greater than or equal to about 250 mA/cm², greater than or equal to about 310 mA/cm², greater than or equal to about 320 mA/cm², or greater than or equal to about 335 mA/cm² and less than or equal to about 500 mA/cm², less than or equal to about 400 mA/cm², or less than or equal to about 350 mA/cm².

In an electroluminescent device of an embodiment, when the zinc oxide nanoparticle is analyzed by UV-Vis absorption spectroscopy, the zinc oxide nanoparticles exhibit a first absorption peak wavelength of greater than or equal to about 285 nm, greater than or equal to about 289 nm, greater than or equal to about 292 nm, or greater than or equal to about 295 nm and less than or equal to about 330 nm, less than or equal to about 315 nm, less than or equal to about 302 nm, less than or equal to about 300 nm, less than or equal to about 299 nm, less than or equal to about 298 nm, or less than or equal to about 297 nm. When the zinc oxide nanoparticle is analyzed by UV-Vis absorption spectroscopy, the zinc oxide nanoparticles exhibit a first absorption peak wavelength of less than or equal to about 320 nm, less than or equal to about 319 nm, less than or equal to about 318 nm, less than or equal to about 317 nm, less than or equal to about 316 nm, less than or equal to about 315 nm, less than or equal to about 314 nm, less than or equal to about 313 nm, less than or equal to about 312 nm, or less than or equal to about 311 nm. The first absorption peak wavelength may be greater than or equal to about 290 nm. The first absorption peak wavelength may be greater than or equal to about 295 nm, greater than or equal to about 300 nm, greater than or equal to about 301 nm, greater than or equal to about 302 nm, or greater than or equal to about 303 nm. In an aspect, when the zinc oxide nanoparticle is analyzed by UV-Vis absorption spectroscopy, a wavelength of a first absorption peak is greater than or equal to about 285 nm and less than or equal to about 300 nm.

When the zinc oxide nanoparticle is analyzed by UV-Vis absorption spectroscopy, the UV-Vis absorption spectrum has a valley that is adjacent to the first absorption peak, and a valley depth of the valley, defined by Equation 1, may be greater than or equal to about 0.01, greater than or equal to about 0.02, greater than or equal to about 0.027, greater than or equal to about 0.03, greater than or equal to about 0.035, greater than or equal to about 0.04, greater than or equal to about 0.045, greater than or equal to about 0.05, greater than or equal to about 0.055, or greater than or equal to about 0.06:

$$1 - ( {Abs}_{valley} / {Abs}_{first} ) = VD \qquad ( 1 )$$

wherein Abs_{first} is an absorbance at a wavelength of the first absorption peak and Abs_{valley} is an absorbance at a lowest point of the valley, and VD is the valley depth.

The valley depth (VD) may be less than or equal to about 0.2, less than or equal to about 0.15, less than or equal to about 0.12, less than or equal to about 0.1, less than or equal to about 0.08, less than or equal to about 0.07, or less than or equal to about 0.06.

In an embodiment, the zinc oxide nanoparticle may exhibit (e.g., have) a bandgap energy of greater than or equal to about 3.6 eV, greater than or equal to about 3.65 eV, greater than or equal to about 3.7 eV, greater than or equal to about 3.75 eV, greater than or equal to about 3.77 eV, greater than or equal to about 3.78 eV, greater than or equal to about 3.79 eV, and less than or equal to about 3.95 eV, less than or equal to about 3.94 eV, less than or equal to about 3.9 eV, less than or equal to about 3.85 eV, less than or equal to about 3.8 eV, less than or equal to about 3.78 eV, less than or equal to about 3.77 eV, less than or equal to about 3.75 eV, or less than or equal to about 3.7 eV. The bandgap energy may be determined by UV-Vis absorption spectroscopy analysis, for example, by X-intercept value of a tangent line of a UV-Vis absorption curve.

In an embodiment, the zinc oxide nanoparticle may exhibit (e.g., have) a dispersibility desired for example in a solution process of the production method of the electroluminescent device. In an embodiment, the zinc oxide nanoparticle may exhibit, as dispersed in an alcohol solvent and measured by dynamic light scattering analysis, an average particle diameter (may be referred to as a DLS average particle diameter, as well) of greater than or equal to about 4.5 nm, greater than or equal to about 5 nm, greater than or equal to about 5.5 nm, greater than or equal to about 6 nm, greater than or equal to about 6.5 nm, greater than or equal to about 7 nm, or greater than or equal to about 7.5 nm. The DLS average particle diameter of the zinc oxide nanoparticle may be less than or equal to about 500 nm, less than or equal to about 300 nm, less than or equal to about 150 nm, less than or equal to about 100 nm, less than or equal to about 50 nm, less than or equal to about 40 nm, less than or equal to about 30 nm, less than or equal to about 20 nm, less than or equal to about 10 nm, less than or equal to about 9 nm, less than or equal to about 8.5 nm, less than or equal to about 8 nm, less than or equal to about 7.5 nm, or less than or equal to about 7 nm. In an aspect, the zinc oxide nanoparticle may have an average particle diameter of greater than or equal to about 5 nm and less than or equal to about 20 nm, when dispersed in the alcohol solvent and the average particle diameter is measured by dynamic light scattering analysis.

In an embodiment, the zinc oxide nanoparticle may have a size or an average size (hereinafter, simply referred to as “size”) of greater than or equal to about 1 nm, greater than or equal to about 3 nm, greater than or equal to about 5 nm, or greater than or equal to about 7 nm. The zinc oxide nanoparticle may have a size of less than or equal to about 50 nm, for example, less than or equal to about 10 nm, less than or equal to about 8 nm, less than or equal to about 7.2 nm, or less than or equal to about 6.2 nm. The size of the zinc oxide nanoparticle may be a diameter or equivalent diameter converted by assuming a spherical shape when not spherical. The size of the zinc oxide nanoparticle may be measured from an electron microscope (e.g., TEM) analysis (e.g., two dimensional TEM image).

In an embodiment, the electron auxiliary layer (e.g., the electron transport layer) including the zinc oxide nanoparticle may be prepared in a solution process. In an embodiment, the electron transport layer may be formed by dispersing the zinc oxide nanoparticle in an organic solvent (e.g., a polar organic solvent, a non-polar organic solvent, or a combination thereof) to obtain a dispersion for forming an electron transport layer and applying the dispersion to form a film. In an embodiment, the dispersion for forming an electron transport layer may be applied on the light emitting layer. The solution process may further include removing the organic solvent from the formed film (e.g., through evaporation or a thermal treatment, etc.). The thermal treatment (i.e., heat treatment) may be conducted at a temperature of greater than or equal to about 50° C., greater than or equal to about 60° C., greater than or equal to about 70° C., or greater than or equal to about 85° C. and less than or equal to about 100° C.

In an embodiment, a thickness of the electron transport layer may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm, and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, but is not limited thereto.

In an embodiment, an electron injection layer may be further disposed between the electron transport layer and the second electrode. The material of the electron injection layer is not particularly limited and can be selected appropriately.

In an embodiment, the electroluminescent device may further include a hole auxiliary layer 2, or 20, between the first electrode 1, or 10, and the light emitting layer 3, or 30. The hole auxiliary layer 2, or 20, may include a hole injection layer, a hole transport layer, an electron blocking layer, or a combination thereof. The hole auxiliary layer 2, or 20, may be a single layer or a multilayer structure in which adjacent layers include different components. (Reference to FIGS. 1 to 3)

The hole auxiliary layer 2, or 20, may have a HOMO energy level that can be matched with the HOMO energy level of the light emitting layer 3, or 30, in order to enhance mobility of holes transferred from the hole auxiliary layer 2, or 20, to the light emitting layer 3, or 30. In an embodiment, the hole auxiliary layer 2, or 20, may include a hole injection layer close to, e.g., adjacent, the first electrode 1, or 10, and a hole transport layer close to, e.g., adjacent, the light emitting layer 3, or 30.

In an embodiment, the material included in the hole auxiliary layer 2, or 20 (e.g., a hole transport layer, a hole injection layer, or an electron blocking layer), is not particularly limited, and may include, for example, poly(9,9-dioctyl-fluorene-co-N-(4)-butylphenyl)-diphenylamine) (TFB), polyarylamine, poly(N-vinylcarbazole), poly(3,4-ethylenedioxythiophene) (PEDOT), poly(3,4-ethylenedioxythiophene):polystyrene sulfonate (PEDOT:PSS), polyaniline, polypyrrole, N,N,N′,N′-tetrakis(4-methoxyphenyl)-benzidine (TPD), 4,4′-bis[N-(1-naphthyl)-N-phenyl-amino]biphenyl (α-NPD), m-MTDATA (4,4′,4″-Tris[phenyl(m-tolyl)amino]triphenylamine), 4,4′,4″-tris(N-carbazolyl)-triphenylamine (TCTA), 1,1-bis[(di-4-toylamino)phenyl]cyclohexane (TAPC), a p-type metal oxide (e.g., NiO, WO₃, MoO₃, etc.), a carbon-based material such as graphene oxide, or a combination thereof, but is not limited thereto.

In the hole auxiliary layer, a thickness of each layer may be appropriately selected. For example, the thickness of each layer may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 35 nm, or less than or equal to about 30 nm, but is not limited thereto.

A device according to an embodiment may have a structure for example, as shown in FIG. 2. In an embodiment, and referring to FIG. 2, in the device, the anode 10 disposed on the transparent substrate 100 may include a metal oxide-based (i.e., metal oxide-containing) transparent electrode (e.g., an ITO electrode), and the cathode 50 facing the anode 10 may include a conductive metal (e.g., having a relatively low work function, such as Mg, Al, etc.). The hole auxiliary layer 20 (e.g., a hole injection layer such as PEDOT:PSS, or p-type metal oxide, or a hole transport layer such as TFB, or polyvinylcarbazole (PVK)) may be provided between the transparent electrode 100 and the light emitting layer 30. The hole injection layer may be disposed close to the transparent electrode and the hole transport layer may be disposed close to the light emitting layer. The electron auxiliary layer 40 including an electron transport layer and optionally an electron injection layer may be disposed between the light emitting layer 30 and the cathode 50. The details of the electron transport layer may be as described above.

A device according to another embodiment may have an inverted structure. Herein, the second electrode 50 disposed on the transparent substrate 100 may include a metal oxide (e.g., ITO)-based transparent electrode, and the anode 10 facing the cathode 50 may include a metal (e.g., having a relatively high work function, such as Au, Ag, etc.). For example, an electron auxiliary layer 40 (including an electron transport layer and optionally an electron injection layer) may be disposed between the transparent electrode 50 and the light emitting layer 30. The details of the electron transport layer may be as described above. MoO₃ or other p-type metal oxide may be disposed as a hole auxiliary layer 20 (e.g., a hole transport layer including TFB, or PVK, or a hole injection layer including MoO₃, or other p-type metal oxide) between the metal anode 10 and the light emitting layer 30. (See FIG. 3)

The above device may be produced by an appropriate method. For example, the electroluminescent device may be produced by optionally forming a hole auxiliary layer (e.g., by deposition or coating) on a substrate on which a first electrode is formed, forming a light emitting layer including semiconductor nanoparticles (e.g., a pattern of the aforementioned semiconductor nanoparticles), forming an electron auxiliary layer (including an electron transport layer) (e.g., by vapor deposition or coating) on the light emitting layer, and forming a second electrode on the electron auxiliary layer. A method of forming the electrode/hole auxiliary layer/light emitting layer may be appropriately selected and is not particularly limited.

In an embodiment, the method may further include forming a hole auxiliary layer on the first electrode (for example, disposed on a substrate), for example via a physical deposition (e.g., a vapor deposition) or a coating process. The method may further include forming an electron injection layer on or over the electron transport layer, and/or forming a hole blocking layer on the light emitting layer. The forming of the electron transport layer is the same as described herein.

An electroluminescent device of an embodiment may exhibit an improved level of electroluminescent properties (e.g., along with an extended life-span as described above).

In an embodiment, the electroluminescent device may have a maximum external quantum efficiency (EQE) of greater than or equal to about 5%, greater than or equal to about 5.5%, greater than or equal to about 6%, greater than or equal to about 6.5%, greater than or equal to about 7%, greater than or equal to about 7.5%, greater than or equal to about 7.7%, greater than or equal to about 8%, greater than or equal to about 8.5%, greater than or equal to about 9%, greater than or equal to about 9.5%, greater than or equal to about 10%, greater than or equal to about 10.5%, greater than or equal to about 11%, greater than or equal to about 11.5%, greater than or equal to about 12%, greater than or equal to about 12.5%, greater than or equal to about 13%, greater than or equal to about 13.5%, or greater than or equal to about 14%. The maximum external quantum efficiency (EQE) may be less than or equal to about 40%, less than or equal to about 30%, or less than or equal to about 20%.

The electroluminescent device of an embodiment may have a maximum luminance of greater than or equal to about 50,000 candelas per square meter (cd/m²), greater than or equal to about 60,000 cd/m², greater than or equal to about 70,000 cd/m², greater than or equal to about 80,000 cd/m², greater than or equal to about 90,000 cd/m², greater than or equal to about 100,000 cd/m², greater than or equal to about 150,000 cd/m², greater than or equal to about 200,000 cd/m², greater than or equal to about 250,000 cd/m², greater than or equal to about 300,000 cd/m², greater than or equal to about 310,000 cd/m², greater than or equal to about 320,000 cd/m², greater than or equal to about 330,000 cd/m², greater than or equal to about 340,000 cd/m², greater than or equal to about 350,000 cd/m², greater than or equal to about 360,000 cd/m², greater than or equal to about 370,000 cd/m², greater than or equal to about 380,000 cd/m², greater than or equal to about 390,000 cd/m², greater than or equal to about 400,000 cd/m², greater than or equal to about 440,000 cd/m², greater than or equal to about 500,000 cd/m², or greater than or equal to about 550,000 cd/m². The maximum luminance may be from about 50,000 cd/m² to about 1,000,000 cd/m², from about 70,000 cd/m² to about 600,000 cd/m², or from about 90,000 cd/m² to about 500,000 cd/m².

The electroluminescent device of an embodiment may be configured to emit blue light, green light, or red light. The peak emission wavelength of the blue light, the peak emission wavelength of the green light, or the peak emission wavelength of the red light are the same as described herein.

In an embodiment, as measured by driving the electroluminescent device at a predetermined initial luminance (for example, about 650 nit), the electroluminescent device may exhibit a T50 of greater than or equal to about 200 hours, greater than or equal to about 250 hours, greater than or equal to about 300 hours, greater than or equal to about 350 hours, greater than or equal to about 400 hours, greater than or equal to about 450 hours, greater than or equal to about 500 hours, greater than or equal to about 550 hours, greater than or equal to about 600 hours, greater than or equal to about 650 hours, or greater than or equal to about 700 hours. The T50 may be from about 275 hours to about 4000 hours, from about 330 hours to about 2000 hours, from about 350 hours to about 1500 hours, from about 420 hours to about 1000 hours, or from about 430 hours to about 900 hours.

In an embodiment, as measured by driving the device at a predetermined initial luminance (for example, about 650 nit), the electroluminescent device may have a T90 of greater than or equal to about 5 hours, e.g., a T90 of greater than or equal to about 10 hours, greater than or equal to about 20 hours, greater than or equal to about 30 hours, greater than or equal to about 40 hours, greater than or equal to about 50 hours, greater than or equal to about 60 hours, greater than or equal to about 70 hours, greater than or equal to about 80 hours, greater than or equal to about 90 hours, greater than or equal to about 100 hours, greater than or equal to about 110 hours, greater than or equal to about 120 hours, greater than or equal to about 130 hours, greater than or equal to about 140 hours, greater than or equal to about 150 hours, greater than or equal to about 160 hours, greater than or equal to about 170 hours, greater than or equal to about 180 hours, greater than or equal to about 190 hours, or greater than or equal to about 200 hours. The T90 may be from about 35 hours to about 1500 hours, from about 55 hours to about 1200 hours, from about 85 hours to about 1000 hours, from about 105 hours to about 900 hours, from about 115 hours to about 800 hours, or from about 145 hours to about 500 hours.

In an aspect, a method of producing an electroluminescent device comprises:
disposing a light emitting layer comprising a semiconductor nanoparticle on a first electrode;
applying a composition comprising a zinc oxide nanoparticle on the light emitting layer to form an electron transport layer, the zinc oxide nanoparticle comprising a first metal different from zinc and an alkali metal; and
disposing the second electrode on the electron transport layer to produce the electroluminescent device,
wherein a preparation of the zinc oxide nanoparticle comprises
   admixing a first solution comprising a zinc precursor and a first metal precursor in a solvent with a second base and optionally a first base to prepare the zinc oxide nanoparticle,
   wherein the first base comprises an organic base comprising a C1 to C50 organic group, and the second base comprises an inorganic base comprising the alkali metal.

In an aspect, an electroluminescent device comprises:
a first electrode and a second electrode spaced apart from each other;
a light emitting layer disposed between the first electrode and the second electrode; and
an electron transport layer disposed between the light emitting layer and the second electrode,
wherein the light emitting layer is configured to emit a first light,
wherein the light emitting layer comprises a semiconductor nanoparticle,
wherein the semiconductor nanoparticle does not comprise cadmium,
wherein the electron transport layer comprises a zinc oxide nanoparticle,
   wherein the zinc oxide nanoparticle has a size of 1 nanometer or greater and 50 nanometers or less, and further comprises
      a first metal and an alkali metal,
      wherein
      the first metal comprises an alkaline earth metal, and optionally zirconium, tungsten, titanium, yttrium, aluminum, gallium, indium, tin, cobalt, vanadium, or a combination thereof, and
      the alkali metal comprises sodium, potassium, rubidium, cesium, francium, or a combination thereof.

Another embodiment relates to a display device including the aforementioned electroluminescent device.

The display device may include a first pixel and a second pixel configured to emit light of a color differing from that of the first pixel. In the first pixel, the second pixel, or both, the electroluminescent device according to an embodiment may be disposed. In an embodiment, the display device may further include a blue pixel, a red pixel, a green pixel, or a combination thereof. In the display device, the red pixel may include a red light emitting layer including a plurality of red light emitting semiconductor nanoparticles, the green pixel may include a green light emitting layer including a plurality of green light emitting semiconductor nanoparticles, and the blue pixel may include a blue light emitting layer including a plurality of blue light emitting semiconductor nanoparticles. The electroluminescent device according to an embodiment may be disposed in the blue pixel, the red pixel, or the green pixel, for example, in the blue pixel.

The display device or an electronic apparatus may include (or may be) a television, a virtual reality/augmented reality (VR/AR) device, a handheld terminal, a monitor, a notebook computer, an electronic display board, a camera, or a part for an automatic, e.g., autonomous, vehicle.

Specific examples are described below. However, the examples described below are only for specifically illustrating or explaining the disclosure, and the scope of the disclosure is not limited thereto.

### EXAMPLES

### 1. Electroluminescence Measurement

A current according to an applied voltage is measured with a Keithley 2635B source meter, and a CS2000 spectrometer is used to measure electroluminescent properties (e.g., luminance and EQE) of a light-emitting device.

### 2. Life-Span Characteristics

T50: As the device is started to be driven at a predetermined luminance (e.g., 650 nit), a time taken for a luminance of a given device to decrease to 50% of its initial luminance is measured.

T90: As the device is started to be driven at a predetermined luminance (e.g., 650 nit), a time taken for a luminance of a given device to decrease to 90% of its initial luminance is measured.

### 3. XPS Analysis

XPS analysis is conducted using X-ray photoelectron spectrometer (manufacturer: Physical Electronics, model name: Quantum2000).

### 4. ICP-AES Analysis

Inductively coupled plasma atomic emission spectroscopy (ICP-AES) analysis is performed using a Shimadzu ICPS-8100.

### 5. TEM Analysis

A transmission electron microscopic analysis of the prepared nanoparticles is conducted using an UT F30 Tecnai electron microscope.

### 6. Photoluminescence Analysis

Photoluminescence (PL) analysis is conducted using a Hitachi F-7100 spectrophotometer.

### 7. UV-Vis Spectroscopy

A UV-Visible absorption spectroscopic analysis is conducted using a Shimadzu UV-2600 spectrophotometer and obtain a UV-Visible absorption spectrum. The bandgap can be obtained from the X-intercept value of the UV-Visible absorption spectrum based on the following equation:

Bandgap energy (eV)=1240 (nm)/a X-intercept value (nm)

### 8. TGA Analysis

A thermogravimetric analysis is conducted under a N₂ atmosphere using a Trios V3.2 system (TA Instruments) at a heating rate of 10° C./min from 20° C. to 600° C.

### 9. FTIR Analysis

A Fourier Transform Infra-red spectroscopy analysis is conducted using Varian 670-IR with Miracle accessory.

The following synthesis is performed under an inert gas atmosphere (e.g., under nitrogen) unless otherwise specified. A precursor content is provided as a molar content, unless otherwise specified.

### Synthesis Example 1

2 moles per liter (M) of a Se/trioctylphosphine (TOP) stock solution, 1M of a S/TOP stock solution, and 0.1M of a Te/TOP stock solution are prepared by dispersing selenium (Se), sulfur (S), and tellurium (Te) in trioctylphosphine (TOP), respectively. In a reactor containing trioctylamine, 0.125 millimoles (mmol) of zinc acetate is added to the reactor with oleic acid and heated at 120° C. under vacuum. After 1 hour, nitrogen is introduced into the reactor.

The reactor is heated to 240° C., and the Se/TOP stock solution and the Te/TOP stock solution in a Te:Se mole ratio of 1:15 are rapidly added to, e.g., injected into, the reactor. When the reaction is complete, the reaction mixture rapidly cooled to room temperature, and acetone is added to facilitate formation of a precipitate. The mixture (suspension) is centrifuged to separate the solids, and then the solids are dispersed in toluene, obtaining a ZnSeTe core (dispersion in toluene).

1.8 mmol of zinc acetate are added together with oleic acid to a flask containing trioctylamine and the prepared mixture is heated at 120° C. under vacuum for 10 minutes. Nitrogen (N₂) is then introduced into the reactor, the reactor is heated to 220° C. The prepared ZnTeSe core particle dispersion is added quickly to the reactor, and the Se/TOP stock solution and the S/TOP stock solution in a Se:S mole ratio of 1:2 are also added to the reactor, and the reactor temperature is raised to about 280° C. After 2 hours, the reaction is complete, and the reactor is cooled to room temperature and ethanol is added to facilitate precipitation of the semiconductor nanoparticles, which are separated by centrifuge.

The prepared semiconductor nanoparticles emit blue light of about 455 nanometers (nm).

### Preparation Example 1

Tetramethylammonium hydroxide (a first base) and rubidium hydroxide (RbOH, a second base) are dissolved (at a mole ratio of the first base:the second base of 1:0.83) in ethanol to obtain a base solution. Zinc acetate dihydrate (in a powder form) and magnesium acetate tetrahydrate (in a powder form) are added into a reactor including dimethylsulfoxide and dissolved therein. Subsequently, the base solution is added into the reactor and the resulting mixture is stirred for 60 minutes at room temperature. Then, ethyl acetate is added to the reaction mixture to facilitate a precipitation of zinc oxide nanoparticles, which are then centrifuged. The separated zinc oxide nanoparticles are dispersed again in ethanol. A TEM analysis is conducted for the obtained nanoparticles, and the result confirms that an average size of the nanoparticles is about 3 nm to 4 nm.

A mole ratio of the magnesium precursor to the zinc precursor is 0.15:0.85.

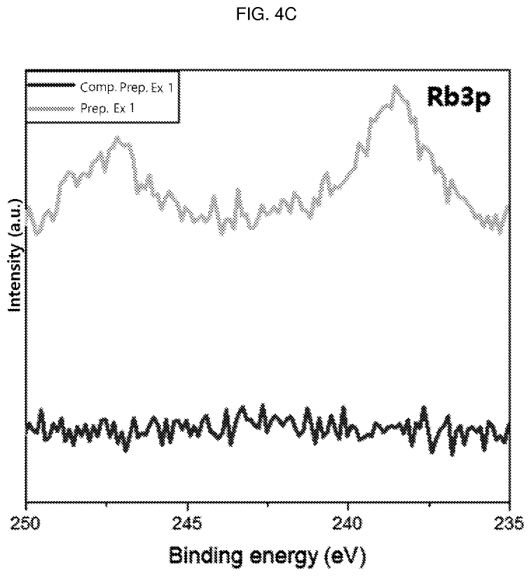

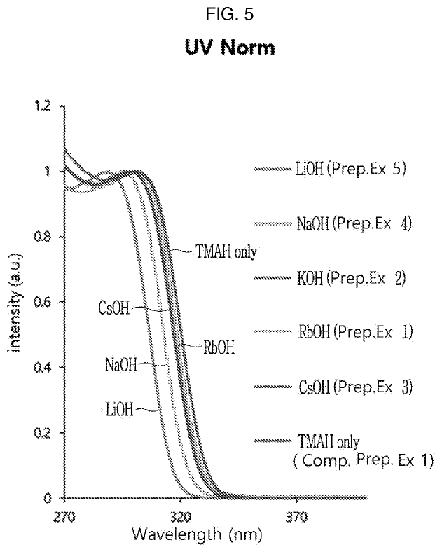

An XPS analysis and a UV-Vis absorption spectroscopy analysis are conducted for the obtained zinc oxide nanoparticles, and the results are shown in Table 1, Table 2, and FIG. 4A, FIG. 4B, FIG. 4C, and FIG. 5. FIG. 4A confirms that the Zn2p peak of the zinc oxide nanoparticle of Example 1 was shifted to lower binding energy by about 0.1 eV than the Zn2p peak of the zinc oxide particles of Comparative Preparation Example 1.

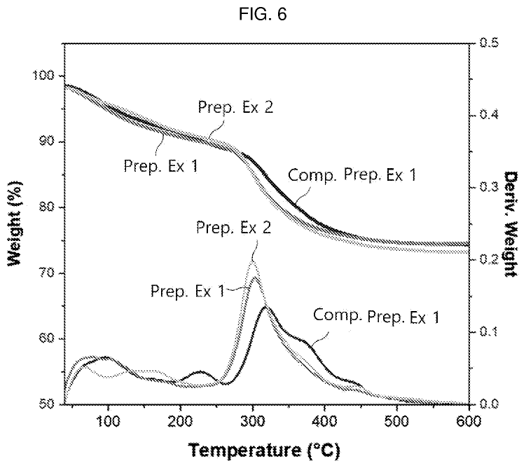

A TGA analysis is conducted for the obtained nanoparticles, and the results are shown in FIG. 6.

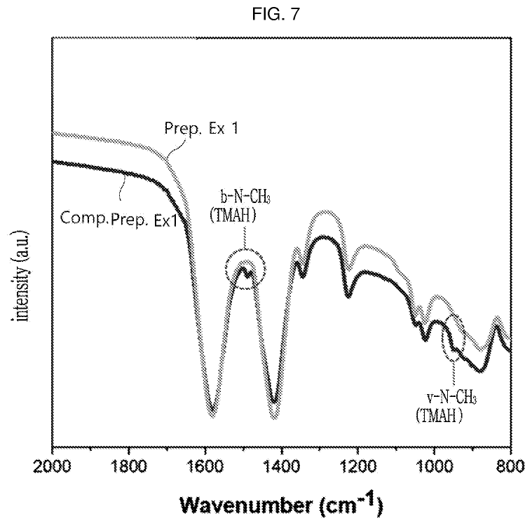

A FTIR spectroscopy analysis is conducted for the obtained nanoparticles, and the results are shown in FIG. 7. FIG. 7 shows that, unlike the zinc oxide nanoparticle of Comparative Preparation Example 1, the zinc oxide nanoparticles of Preparation Example 1 do not exhibit a peak assigned to an amine group in a wavenumber range of from about 1485 centimeters⁻¹ to about 1490 centimeters⁻¹ in a Fourier transform infrared spectrum. FIG. 7 shows that, unlike the zinc oxide nanoparticle of Comparative Preparation Example 1, the zinc oxide nanoparticles of Preparation Example 1 do not exhibit a peak assigned to an amine group in a wavenumber range of from about 920 centimeters⁻¹ to about 1000 centimeters⁻¹ in a Fourier transform infrared spectrum.

### Comparative Preparation Example 1

Zinc oxide nanoparticles are prepared in the same manner as Preparation Example 1, except for not using the second base (i.e., rubidium hydroxide).

An XPS analysis and a UV-Vis absorption spectroscopy analysis are conducted for the obtained zinc oxide nanoparticles, and the results are shown in Table 1, Table 2, and FIG. 4A, FIG. 4B, FIG. 4C, and FIG. 5. A TGA analysis is conducted for the obtained nanoparticles, and the results are shown in FIG. 6. A FTIR spectroscopy analysis is conducted for the obtained nanoparticles, and the results are shown in FIG. 7.

### Preparation Example 2

Zinc oxide nanoparticles are prepared in the same manner as Preparation Example 1, except for using potassium hydroxide (KOH) instead of the rubidium hydroxide as the second base.

A UV-Vis absorption spectroscopy analysis is conducted for the obtained zinc oxide nanoparticles, and the results are shown in Table 2 and FIG. 5. An ICP-AES analysis is conducted for the prepared zinc oxide nanoparticles, and the results are summarized in Table 3.

A TGA analysis is conducted for the obtained nanoparticles, and the results are shown in FIG. 6.

### Preparation Example 3

Zinc oxide nanoparticles are prepared in the same manner as Preparation Example 1, except for using cesium hydroxide (CsOH) instead of the rubidium hydroxide as the second base.

A UV-Vis absorption spectroscopy analysis is conducted for the obtained zinc oxide nanoparticles, and the results are shown in Table 2 and FIG. 5.

### Preparation Example 4

Zinc oxide nanoparticles are prepared in the same manner as Preparation Example 1, except for using sodium hydroxide (NaOH) instead of the rubidium hydroxide as the second base.

A UV-Vis absorption spectroscopy analysis is conducted for the obtained zinc oxide nanoparticles, and the results are shown in Table 2 and FIG. 5.

### Preparation Example 5

Zinc oxide nanoparticles are prepared in the same manner as Preparation Example 1, except for using lithium hydroxide (LiOH) instead of the rubidium hydroxide as the second base.

A UV-Vis absorption spectroscopy analysis is conducted for the obtained zinc oxide nanoparticles, and the results are shown in Table 2 and FIG. 5.

### Comparative Preparation Example 2

Zinc oxide nanoparticles are prepared in the same manner as Preparation Example 1, except for using lithium hydroxide (LiOH) instead of the rubidium hydroxide as the second base and not using the first base.

The obtained zinc oxide nanoparticles do not form a transparent coating liquid (e.g., a colloidal dispersion) and it is difficult for a composition including the same to provide coating properties for the formation of an electron transport layer.

### Preparation Example 6

Zinc oxide nanoparticles are prepared in the same manner as Preparation Example 1, except for not using the first base.

A UV-Vis absorption spectroscopy analysis and an XPS spectroscopy analysis are conducted for the obtained zinc oxide nanoparticles. The results confirmed that the Zn2p peak of the zinc oxide nanoparticles was shift to a lower binding energy by about 0.1 eV than the zinc oxide nanoparticles of Comparative Preparation Example 1, and a VD of the zinc oxide nanoparticles is 0.09.

### Preparation Example 7

Zinc oxide nanoparticles are prepared in the same manner as Preparation Example 1, except for not using the first base and using cesium hydroxide instead of rubidium hydroxide.

A UV-Vis absorption spectroscopy analysis is conducted for the obtained zinc oxide nanoparticles. The results confirmed that a VD of the zinc oxide nanoparticles is 0.076.

TABLE 1

| | | | | (Mg + Rb)/ |
|---|---|---|---|---|
| | C/Zn ^{note1} | Rb/Mg ^{note2} | Rb/Zn ^{note3} | Zn ^{note4} |
| Comparative | 0.997 | 0 | 0 | 0.1413 |
| Preparation | | | | |
| Example 1 | | | | |
| Preparation | 1.417 | 0.6484 | 0.1081 | 0.2747 |
| Example 1 | | | | |

^{note1}
an intensity ratio of C1s peak/Zn2p1 peak
^{note2}
an intensity ratio of Rb3p peak/Mg2p peak
^{note3}
an intensity ratio of Rb3p peak/Zn2p1 peak
^{note4}
an intensity ratio of (Rb3p peak + Mg2p peak)/Zn2p1 peak

From the results of Table 1 and FIGS. 4A, 4B, and 4C, it is confirmed that the zinc oxide nanoparticles of Preparation Example 1 contain rubidium.

TABLE 2

| | | First absorption | | |
|---|---|---|---|---|
| | | peak wavelength | Bandgap | |
| | Second | (the X intercept | energy | |
| | base | wavelength) | (eV)^{note 5} | Valley depth |
| Preparation | — | 302 nm (330.7 nm) | 3.7496 | 0.027 |
| Comparative | | | | |
| Example 1 | | | | |
| Preparation | RbOH | 299 nm (328.6 nm) | 3.7736 | 0.047 |
| Example 1 | | | | |
| Preparation | KOH | 297 nm (327.5 nm) | 3.7863 | 0.04 |
| Example 2 | | | | |
| Preparation | CsOH | 296 nm (327.2 nm) | 3.7897 | 0.038 |
| Example 3 | | | | |
| Preparation | NaOH | 295 nm (322.2 nm) | 3.8485 | 0.063 |
| Example 4 | | | | |
| Preparation | LiOH | 289 nm (316.2 nm) | 3.9216 | 0.053 |
| Example 5 | | | | |

^{note 5}
Bandgap energy = 1240/x intercept (eV)

The results of Tables 2 and 5 confirmed that the zinc oxide nanoparticles of the preparation examples (prepared by using the second base and the first base together) exhibit the UV-Vis absorption characteristics and the bandgap energy that are different from the zinc oxide nanoparticles of the Comparative Preparation Example 1 prepared without using the second base. It is also confirmed that the first absorption peak wavelength and the bandgap energy change (increase or decrease) depending on the type (or the cation radius) of the alkali metal.

TABLE 3

| | K/Mg | K/Zn | (Mg + K)/Zn |
|---|---|---|---|
| Preparation Example 2 | 0.4861 | 0.0391 | 0.1197 |

The results of Table 3 confirmed that the zinc oxide nanoparticles of Preparation Example 2 include potassium. The thermogravimetric analysis results of FIG. 6 confirmed that the zinc oxide nanoparticles of the preparation examples exhibit the DTG peaks at lower temperatures (for example, below about 300° C.) than the zinc oxide nanoparticles of the preparation comparative example, the use of the alkali metal hydroxides such as RbOH does not substantially change a total amount of the organic matter, but a decomposition of the carbon containing group (e.g., an organic functional group) may be accelerated at a relatively low temperature range.

As an amount of an alkali metal hydroxide such as RbOH increases, the amount of decomposition at lower temperatures may also increase. Without wishing to be bound by any theory, the TGA analysis may suggest a change in the surface functional group distribution of the nanoparticle caused by the use of a second base.

### Experimental Example 1: Electron Only Device (EOD) Analysis

The semiconductor nanoparticles of Synthesis Example 1 are dispersed in octane to prepare a semiconductor nanoparticle solution.

Each of the zinc oxide nanoparticles of Preparation Example 1 (RbOH), Preparation Example 2 (KOH), and Preparation Example 3 (CsOH) are dispersed in ethanol to provide respective first dispersions for forming ETL.

The zinc oxide nanoparticles of Comparative Preparation Example 1 (ZMO) are dispersed in ethanol to prepare a second dispersion.

According to the following methods, an electron only device (EOD) with a structure of ITO/ZMO/EML/ETL/Al is manufactured.

The second dispersion is spin-coated on a glass substrate deposited with an ITO electrode (anode) and then, heat-treated at 80° C. for 30 minutes, forming an electron auxiliary layer (ETL1, thickness: 30 nm).

On the electron auxiliary layer, the semiconductor nanoparticle solution is spin-coated, forming a light emitting layer having a thickness of about 20 nm. On the light emitting layer, the first dispersion is used to form an electron transport layer (ETL2, thickness: 30 nm), and then, an Al electrode is deposited thereon.

A current density (mA/cm²) is measured with a change in voltage, increasing (forward scan) and decreasing (backward scan) within a range of 0 to 8 V between the ITO electrode and the Al electrode, and the results are shown in Table 4.

TABLE 4

| | | | In 3^{rd} sweep, |
|---|---|---|---|
| | Zinc oxide | Zinc oxide | current |
| | nanoparticle in | nanoparticle in | density at 8 V |
| | ETL 1 | ETL 2 | (mA/cm²) |
| EOD 1 | Comparative | Preparation Example 1 | 239 |
| | Preparation Example 1 | (RbOH) | |
| EOD 2 | Comparative | Preparation Example 2 | 331 |
| | Preparation Example 1 | (KOH) | |
| EOD 3 | Comparative | Preparation Example 3 | 257 |
| | Preparation Example 1 | (CsOH) | |
| EOD 4 | Comparative | Comparative | 62 |
| | Preparation Example 1 | Preparation Example 1 | |

The results of Table 4 confirmed that the device including the electron transport layer ETL2 based on the zinc oxide nanoparticles prepared in the preparation examples may exhibit a significantly higher current density than that of a device including ETL 2 based on the zinc oxide nanoparticles of Comparative Preparation Example 1. Without wishing to be bound by any theory, these results indicate that in the cases of the zinc oxide nanoparticles of the preparation Examples, the electron mobility may increase and the trap sites of the particle may be passivated, facilitating the electron movement.

### Production of Electroluminescent Device

### Example 1

A semiconductor nanoparticle solution is prepared by dispersing the semiconductor nanoparticles prepared in Synthesis Example 1 in octane. An ETL dispersion is prepared by dispersing the zinc oxide nanoparticles prepared in Preparation Example 1 in ethanol.

An electroluminescent device (ITO/PEDOT (35 nm)/TFB (25 nm)/QD light emitting layer (20 nm)/ETL (20 nm)/Al (100 nm)) is produced according to the following method.

After surface-treating a glass substrate deposited with ITO with UV-ozone for 15 minutes, a PEDOT:PSS solution (H.C. Starks, Inc.) is spin-coated thereon and heat-treated at 150° C. for 10 minutes under an air atmosphere and then, at 150° C. for 20 to 30 minutes under an N₂ atmosphere to form a 35 nm-thick hole injection layer.

On the hole injection layer, a poly[(9,9-dioctylfluorenyl-2,7-diyl-co (4,4′-(N-4-butylphenyl)diphenylamine] solution (TFB) (Sumitomo Corp.) is spin-coated and heat-treated at 150° C. for 30 minutes, forming a 25 nm-thick hole transport layer.

On the hole transport layer, the semiconductor nanoparticle solution is spin-coated to form a 20 nm-thick light emitting layer.

On the light emitting layer, the ETL dispersion is spin-coated and heat-treated for 30 minutes, forming an electron transport layer (thickness: 20 nm).

On the obtained electron transport layer, aluminum (Al) is vacuum-deposited to be 100 nm thick, forming a second electrode and thus producing an electroluminescent device.

Electroluminescent properties and life-span of the produced electroluminescent device are measured and the results are shown in Table 5.

### Comparative Example 1

An electroluminescent device is manufactured in the same manner as in Example 1 except that ETL dispersion prepared by dispersing the zinc oxide nanoparticles of Comparative Preparation Example 1 in ethanol is used to form the electron transport layer. Electroluminescent properties and life-span of the produced electroluminescent device are measured and the results are shown in Table 5.

The prepared device exhibits a T90 of greater than 60 hours (for example, greater than or equal to about 63 hours) and a T50 of greater than 250 hours (for example, greater or equal to about 260 hours)

TABLE 5

| | Zinc oxide | | Max. | | | |
|---|---|---|---|---|---|---|
| | nanoparticles | Max. | Lumi- | Relative | Relative | EL |
| | included in | EQE | nance | T90 | T50 | PWL |
| | the ETL | (%) | (Cd/m²) | (hour) | (hour) | (nm) |
| Example 1 | Preparation | About | 109404 | 160% | 134% | about |
| | Example 1 | 10% | | | | 480 |
| Comparative | Comparative | About | 101966 | 100% | 100% | about |
| Example 1 | Preparation | 10% | | | | 480 |
| | Example 1 | | | | | |

Relative T90(%): A percentage of a T90 (hours) of a given device relative to the T90 (hours) of the device of Comparative Example 1

Relative T50(%): A percentage of a T50 (hours) of a given device relative to the T50 (hours) of the device of Comparative Example 1

EL PWL: peak emission wavelength of the electroluminescent spectrum

From the results of Table 5, it is confirmed that the electroluminescent device of Example 1 exhibits improved electroluminescent properties and extended life characteristics compared to the device of Comparative Example 1.

### Example 2

An electroluminescent device is manufactured in the same manner as in Example 1 except that ETL dispersion prepared by dispersing the zinc oxide nanoparticles of Preparation Example 6 in ethanol is used. A relative T90 of the produced electroluminescent device is measured to be 130% or greater.

### Example 3

An electroluminescent device is manufactured in the same manner as in Example 1 except that ETL dispersion prepared by dispersing the zinc oxide nanoparticles of Preparation Example 7 in ethanol is used. A relative T90 of the produced electroluminescent device is measured to be 130% or greater.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A method of producing an electroluminescent device, the method comprising:
disposing a light emitting layer comprising a semiconductor nanoparticle on a first electrode;
applying a composition comprising a zinc oxide nanoparticle on the light emitting layer to form an electron transport layer, the zinc oxide nanoparticle comprising a first metal different from zinc and an alkali metal; and
disposing the second electrode on the electron transport layer to produce the electroluminescent device,
wherein a preparation of the zinc oxide nanoparticle comprises
admixing a first solution comprising a zinc precursor and a first metal precursor in a solvent with a second base and optionally a first base to prepare the zinc oxide nanoparticle,
wherein the first base comprises an organic base comprising a C1 to C50 organic group, and the second base comprises an inorganic base comprising the alkali metal.

2. The method of claim 1,
wherein
the first metal comprises an alkaline earth metal, zirconium, tungsten, titanium, yttrium, aluminum, gallium, indium, tin, cobalt, vanadium, or a combination thereof, and
the alkali metal comprises sodium, potassium, rubidium, cesium, francium, or a combination thereof, and
optionally wherein the first solution is prepared by dissolving the zinc precursor and the first metal precursor in the solvent.

3. The method of claim 1, wherein the first base comprises a quaternary ammonium salt, and the second base comprises a hydroxide of the alkali metal.

4. The method of claim 1, wherein a mole ratio of the second base to the first base is from about 1:0 to about 1:10.

5. The method of claim 1, wherein when the zinc oxide nanoparticle is analyzed by ultraviolet-visible absorption spectroscopy,
a wavelength of a first absorption peak in an ultraviolet-visible absorption spectrum is greater than or equal to about 285 nanometers and less than or equal to about 300 nanometers, and
optionally wherein the ultraviolet-visible absorption spectrum has a valley that is adjacent to the first absorption peak, and a valley depth of the valley, defined by Equation 1, is greater than or equal to about 0.03 and less than or equal to about 0.15:
$$1 - ( {Abs}_{valley} / {Abs}_{first} ) = VD \qquad ( 1 )$$
wherein Abs_{first} is an absorbance at the wavelength of the first absorption peak and Abs_{valley} is an absorbance at a lowest point of the valley, and VD is the valley depth.

6. The method of claim 1, wherein the zinc oxide nanoparticle has a bandgap energy of greater than or equal to about 3.6 electronvolts and less than or equal to about 3.95 electronvolts; or
wherein the zinc oxide nanoparticle has a size of greater than or equal to about 1 nanometer and less than or equal to about 50 nanometers.

7. The method of claim 1, wherein in the zinc oxide nanoparticle, a mole ratio of the alkali metal to the first metal is greater than or equal to about 0.05:1 and less than or equal to about 1.5:1.

8. The method of claim 1, wherein in the zinc oxide nanoparticle, a mole ratio of the alkali metal to zinc is greater than or equal to about 0.01:1 and less than or equal to about 0.5:1.

9. The method of claim 1, wherein in the zinc oxide nanoparticle, a mole ratio of a sum of the first metal and the alkali metal to zinc is greater than or equal to about 0.1:1 and less than or equal to about 1:1.

10. The method of claim 1, wherein the zinc oxide nanoparticle is configured to be dispersible in a C1 to C10 alcohol solvent to form a colloidal dispersion.

11. The method of claim 1,
wherein
when the zinc oxide nanoparticle is analyzed by X-ray photoelectron spectroscopy, a Zn2p peak of the zinc oxide nanoparticle is shifted to a lower binding energy than a Zn2p peak of a zinc oxide nanoparticle that is prepared using the first base and without using the second base, or
when the zinc oxide nanoparticle is analyzed by Fourier transform infrared spectroscopy, a Fourier transform infrared spectrum does not have a peak assigned to an amine group in a wavenumber range of from about 1485 centimeters⁻¹ to about 1490 centimeters⁻¹.

12. An electroluminescent device comprising:
a first electrode and a second electrode spaced apart from each other;
a light emitting layer disposed between the first electrode and the second electrode; and
an electron transport layer disposed between the light emitting layer and the second electrode,
wherein the light emitting layer is configured to emit a first light,
wherein the light emitting layer comprises a semiconductor nanoparticle,
wherein the semiconductor nanoparticle does not comprise cadmium,
wherein the electron transport layer comprises a zinc oxide nanoparticle,
wherein the zinc oxide nanoparticle has a size of greater than or equal to about 1 nanometer and less than or equal to about 50 nanometers, and comprises
a first metal and an alkali metal,
wherein
the first metal comprises an alkaline earth metal, and optionally zirconium, tungsten, titanium, yttrium, aluminum, gallium, indium, tin, cobalt, vanadium, or a combination thereof, and
the alkali metal comprises sodium, potassium, rubidium, cesium, francium, or a combination thereof.

13. The electroluminescent device of claim 12, wherein the first light is blue light and a peak emission wavelength of the first light is greater than or equal to about 440 nanometers and less than or equal to about 480 nanometers.

14. The electroluminescent device of claim 12, wherein, in the zinc oxide nanoparticle, the first metal is magnesium, and the alkali metal comprises potassium, rubidium, cesium, or a combination thereof.

15. The electroluminescent device of claim 12, wherein the electron transport layer is configured to exhibit a bandgap energy of greater than or equal to about 3.5 electronvolts and less than or equal to about 3.95 electronvolts.

16. The electroluminescent device of claim 12, wherein in the zinc oxide nanoparticle,
a mole ratio of the alkali metal to the first metal is greater than or equal to about 0.36:1 and less than or equal to about 0.7:1, and
a mole ratio of the alkali metal to zinc is greater than or equal to about 0.01:1 and less than or equal to about 0.5:1.

17. The electroluminescent device of claim 12, wherein in the zinc oxide nanoparticle,
a mole ratio of a sum of the first metal and the alkali metal to zinc is greater than or equal to about 0.1:1 and less than or equal to about 1:1.

18. The electroluminescent device of claim 12, wherein when the zinc oxide nanoparticle is analyzed by ultraviolet-visible absorption spectroscopy,
a wavelength of a first absorption peak in an ultraviolet-visible absorption spectrum is greater than or equal to about 290 nanometers and less than or equal to about 300 nanometers, and
optionally wherein the ultraviolet-visible absorption spectrum has a valley that is adjacent to the first absorption peak, and a valley depth of the valley, defined by Equation 1, is greater than or equal to about 0.03 and less than or equal to about 0.15:
$$1 - ( {Abs}_{valley} / {Abs}_{first} ) = VD \qquad ( 1 )$$
wherein Abs_{first} is an absorbance at the first absorption peak wavelength and Abs_{valley} is an absorbance at a lowest point of the valley, and VD is the valley depth.

19. The electroluminescent device of claim 12,
wherein the electroluminescent device is configured to emit blue light on an application of a voltage;
wherein
the electroluminescent device has a maximum external quantum efficiency of greater than or equal to about 6 percent and less than or equal to about 40 percent, or
the electroluminescent device shows a maximum luminance of greater than or equal to about 50,000 candelas per square meter and less than or equal to about 500,000 candelas per square meter; and
wherein the electroluminescent device exhibits a T90 of greater than or equal to about 50 hours as measured at an initial luminance of 650 nit.

20. A display device comprising the electroluminescent device of claim 12.

21. The display device of claim 20, wherein the display device comprises a handheld terminal device, a monitor, a notebook computer, a television, an electronic display board, a camera, or an electronic component for an automatic vehicle.
